(19) United States
(12) Patent Application Publication
(10) Pub. No.: US 2025/0299708 A1
(43) Pub. Date: Sep. 25, 2025

(54) SEMICONDUCTOR MEMORY DEVICE

(71) Applicant: Kioxia Corporation, Tokyo (JP)

(72) Inventors: Takafumi MASUDA, Kawasaki Kanagawa (JP); Mutsumi OKAJIMA, Yokkaichi Mie (JP)

(73) Assignee: Kioxia Corporation, Tokyo (JP)

(21) Appl. No.: 19/076,753

(22) Filed: Mar. 11, 2025

(30) Foreign Application Priority Data
Mar. 21, 2024 (JP) 2024-044804

(51) Int. Cl. G11C 5/06; H10B 51/10; H10B 51/20; H10B 53/10; H10B 53/20

(52) U.S. Cl. CPC G11C 5/063; H10B 51/10; H10B 51/20; H10B 53/10; H10B 53/20

(57) ABSTRACT

A semiconductor memory device includes: a substrate; a first via-wiring extending in a first direction; first semiconductor layers electrically connected to the first via-wiring; memory portions electrically connected to the first semiconductor layers; first gate electrodes opposed to the first semiconductor layers; first wirings extending in a second direction, and electrically connected to the first gate electrodes; second semiconductor layers electrically connected to the first wirings; second gate electrodes opposed to the plurality of second semiconductor layers; a second via-wiring extending in the first direction and electrically connected to the second gate electrodes; and a second wiring extending in the first direction, electrically connected to the second semiconductor layers, and arranged with the second semiconductor layers in a third direction.

### CROSS-REFERENCE TO RELATED APPLICATIONS

This application is based upon and claims the benefit of Japanese Patent Application No. 2024-044804, filed on Mar. 21, 2024, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic circuit diagram for describing a read operation of the semiconductor memory device;

FIG. 3 is a schematic perspective view illustrating a configuration of a part of the semiconductor memory device;

FIG. 4 is a schematic perspective view illustrating a configuration of a part of the semiconductor memory device;

FIG. 5 is a schematic X-Y cross-sectional view illustrating a configuration of a part of the semiconductor memory device;

FIG. 6 is a schematic X-Y cross-sectional view illustrating a configuration of a part of the semiconductor memory device;

FIG. 7 is a schematic X-Y cross-sectional view illustrating a configuration of a part of the semiconductor memory device;

FIG. 8 is a schematic cross-sectional view illustrating a configuration of a part of the semiconductor memory device;

FIG. 9 is a schematic X-Y cross-sectional view illustrating a configuration of a part of the semiconductor memory device;

FIG. 10 is a schematic cross-sectional view illustrating a configuration of a part of the semiconductor memory device;

FIG. 11 is a schematic X-Y cross-sectional view illustrating a configuration of a part of the semiconductor memory device;

FIG. 12 is a schematic cross-sectional view illustrating a configuration of a part of the semiconductor memory device;

FIG. 13 is a schematic X-Y cross-sectional view illustrating a configuration of a part of the semiconductor memory device;

FIG. 14 is a schematic cross-sectional view illustrating a configuration of a part of the semiconductor memory device;

FIG. 15 is a schematic cross-sectional view illustrating a configuration of a part of the semiconductor memory device;

FIG. 16 is a schematic cross-sectional view for describing a manufacturing method of the semiconductor memory device;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic cross-sectional view for describing the manufacturing method;

FIG. 84 is a schematic cross-sectional view for describing the manufacturing method;

FIG. 85 is a schematic cross-sectional view for describing the manufacturing method;

FIG. 86 is a schematic cross-sectional view for describing the manufacturing method;

FIG. 87 is a schematic cross-sectional view for describing the manufacturing method;

FIG. 88 is a schematic cross-sectional view for describing the manufacturing method;

FIG. 89 is a schematic cross-sectional view for describing the manufacturing method;

FIG. 90 is a schematic cross-sectional view for describing the manufacturing method;

FIG. 91 is a schematic cross-sectional view for describing the manufacturing method;

FIG. 92 is a schematic cross-sectional view for describing the manufacturing method;

FIG. 93 is a schematic cross-sectional view for describing the manufacturing method;

FIG. 94 is a schematic cross-sectional view for describing the manufacturing method;

FIG. 95 is a schematic cross-sectional view for describing the manufacturing method;

FIG. 96 is a schematic cross-sectional view for describing the manufacturing method;

FIG. 97 is a schematic cross-sectional view for describing the manufacturing method;

FIG. 98 is a schematic cross-sectional view for describing the manufacturing method;

FIG. 99 is a schematic cross-sectional view for describing the manufacturing method;

FIG. 100 is a schematic cross-sectional view for describing the manufacturing method;

FIG. 101 is a schematic cross-sectional view for describing the manufacturing method;

FIG. 102 is a schematic cross-sectional view for describing the manufacturing method;

FIG. 103 is a schematic cross-sectional view for describing the manufacturing method;

FIG. 104 is a schematic cross-sectional view for describing the manufacturing method;

FIG. 105 is a schematic cross-sectional view for describing the manufacturing method;

FIG. 106 is a schematic cross-sectional view for describing the manufacturing method;

FIG. 107 is a schematic cross-sectional view for describing the manufacturing method;

FIG. 108 is a schematic cross-sectional view for describing the manufacturing method;

FIG. 109 is a schematic cross-sectional view for describing the manufacturing method;

FIG. 110 is a schematic cross-sectional view for describing the manufacturing method;

FIG. 111 is a schematic cross-sectional view for describing the manufacturing method;

FIG. 112 is a schematic cross-sectional view for describing the manufacturing method;

FIG. 113 is a schematic cross-sectional view for describing the manufacturing method;

FIG. 114 is a schematic cross-sectional view for describing the manufacturing method;

FIG. 115 is a schematic cross-sectional view for describing the manufacturing method;

FIG. 116 is a schematic cross-sectional view for describing the manufacturing method;

FIG. 117 is a schematic cross-sectional view for describing the manufacturing method;

FIG. 118 is a schematic cross-sectional view for describing the manufacturing method; and

FIG. 119 is a schematic X-Y cross-sectional view illustrating a configuration of a part of a semiconductor memory device according to a second embodiment.

### DETAILED DESCRIPTION

A semiconductor memory device according to one embodiment comprises: a substrate; a first via-wiring extending in a first direction intersecting with a surface of the substrate; a plurality of first semiconductor layers arranged in the first direction and electrically connected to the first via-wiring; a plurality of memory portions arranged in the first direction and electrically connected to the plurality of first semiconductor layers; a plurality of first gate electrodes arranged in the first direction and opposed to the plurality of first semiconductor layers; a plurality of first wirings arranged in the first direction, extending in a second direction intersecting with the first direction, and electrically connected to the plurality of first gate electrodes; a plurality of second semiconductor layers arranged in the first direction and electrically connected to the plurality of first wirings; a plurality of second gate electrodes arranged in the first direction and opposed to the plurality of second semiconductor layers; a second via-wiring extending in the first direction and electrically connected to the plurality of second gate electrodes; and a second wiring extending in the first direction, electrically connected to the plurality of second semiconductor layers, and arranged with the plurality of second semiconductor layers in a third direction intersecting with the first direction and the second direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the above-described Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, a “center position” of a certain configuration may mean, for example, a position of the center of a circumscribed circle of this configuration, and may mean the centroid on an image of this configuration on a predetermined plane.

### First Embodiment

### Circuit Configuration

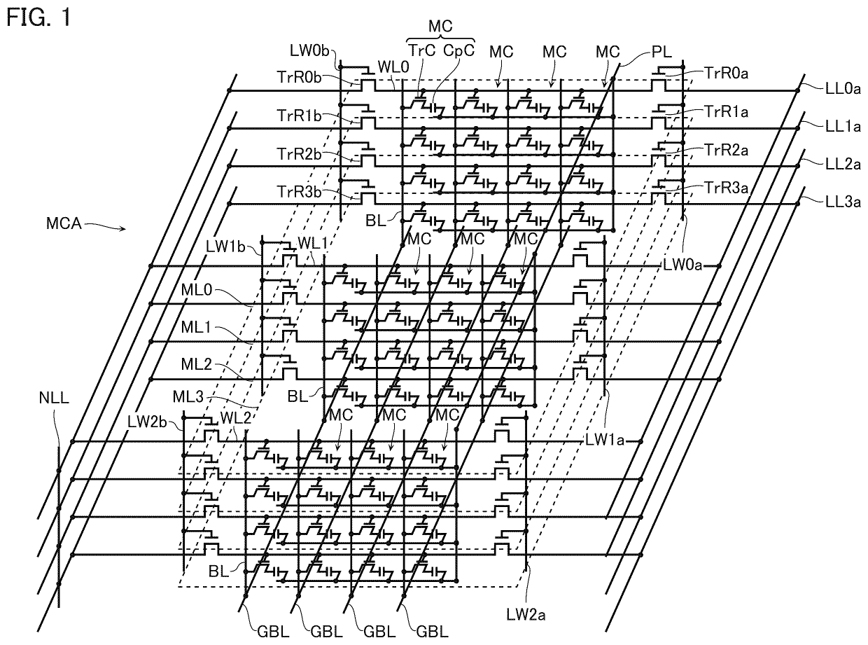

FIG. 1 is a schematic circuit diagram illustrating a configuration of a part of a semiconductor memory device according to a first embodiment. As illustrated in FIG. 1, the semiconductor memory device according to the embodiment includes a memory cell array MCA. The memory cell array MCA includes a plurality of memory layers ML0 to ML3 (hereinafter referred to as “memory layer ML” in some cases), a plurality of bit lines BL connected to these plurality of memory layers ML0 to ML3, a plurality of global bit lines GBL electrically connected to the plurality of bit lines BL, and a plate line PL connected to the plurality of memory layers ML0 to ML3.

Each of the memory layers ML0 to ML3 includes a plurality of word lines WL0 to WL2 (hereafter, “word line WL” in some cases), and a plurality of memory cells MC connected to these plurality of word lines WL0 to WL2. Each of the memory cells MC includes a transistor TrC and a capacitor CpC. One electrode of the transistor TrC is connected to the bit line BL. The other electrode of the transistor TrC is connected to the capacitor CpC. The one electrode and the other electrode of the transistor TrC function as a source electrode or a drain electrode, depending on a voltage applied to the transistor TrC. A gate electrode of the transistor TrC is connected to any of the word lines WL0 to WL2. One of the electrodes of the capacitor Cpc is connected to the other electrode of the transistor TrC. The other electrode of the capacitor Cpc is connected to the plate line PL.

In addition, each bit line BL is connected to the plurality of memory cells MC corresponding to the plurality of memory layers ML0 to ML3. In addition, each bit line BL is connected to the global bit line GBL.

In addition, each of the memory layers ML0 to ML3 includes a plurality of transistors TrR0a, TrR1a, TrR2a, TrR3a (hereinafter referred to as “transistors TrRa” in some cases) and a plurality of transistors TrR0b, TrR1b, TrR2b, TrR3b (hereafter, “transistors TrRb” in some cases) provided corresponding to the plurality of word lines WL0 to WL2. One electrodes of the transistors TrRa, TrRb are connected to any of the word lines WL0 to WL2. The other electrodes of the transistors TrR0a, TrR1a, TrR2a, TrR3a are connected to respective layer select lines LL0a, LL1a, LL2a, LL3a (hereafter, the “layer select lines LL” in some cases). The other electrodes of the transistors TrR0b, TrR1b, TrR2b, TrR3b are connected to a wiring NLL, respectively. The one electrodes and the other electrodes of the transistors TrRa, TrRb function as source electrodes or drain electrodes depending on voltages applied to the transistors TrRa, TrRb. The gate electrodes of the transistors TrRa, TrRb are connected to respective word line select lines LW0a, LW1a, LW2a, LW0b, LW1b, LW2b (hereafter, “word line select lines LW” in some cases).

In addition, the word line select line LW is connected to the plurality of transistors TrRa, TrRb corresponding to the plurality of memory layers ML0 to ML3. In addition, each of the layer select lines LL0a, LL1a, LL2a, LL3a is connected in common to all the transistors TrR0a, TrR1a, TrR2a, TrR3a corresponding to the memory layers ML0 to ML3. The wiring NLL is connected in common to all the transistors TrR0b, TrR1b, TrR2b, TrR3b corresponding to all the word lines WL0, WL1, WL2.

### Read Operation

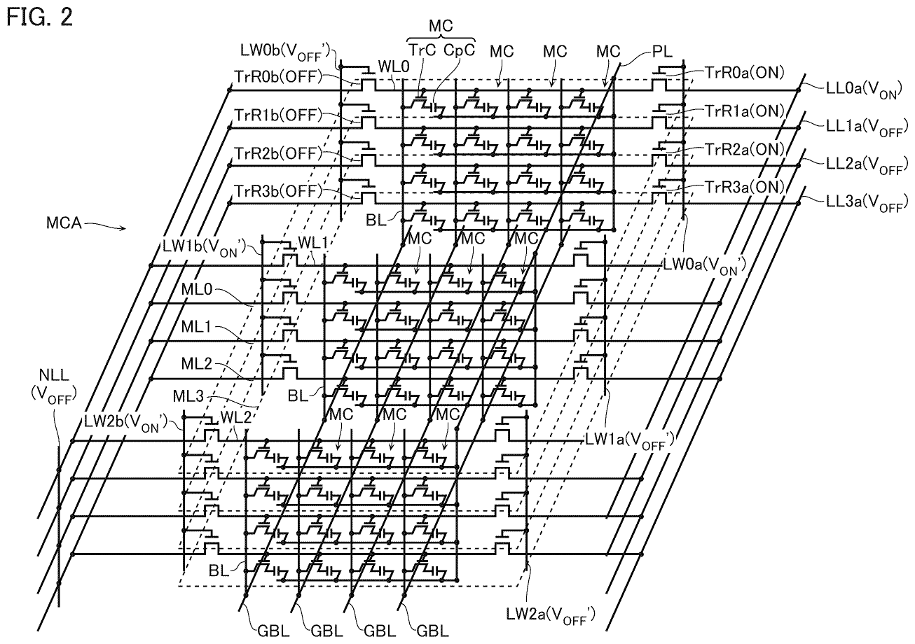

FIG. 2 is a schematic circuit diagram for describing a read operation of the semiconductor memory device according to the first embodiment.

When a read operation is performed, one of the plurality of memory layers ML0 to ML3 is selected. In the illustrated example, the memory layer ML0 is selected. When selecting the memory layers ML0 to ML3, for example, a voltage V_{ON} is applied to the layer select line LL0a corresponding to the memory layer ML0 as a target of the read operation among the plurality of layer select lines LL0a, LL1a, LL2a, LL3a, and a voltage V_{OFF} is applied to the other layer select lines LL1a, LL2a, LL3a. For example, the voltage V_{OFF} is applied to the wiring NLL.

The voltage V_{ON} has a magnitude that is sufficient to cause the transistor TrC to enter the ON state, for example. The voltage V_{OFF} has a magnitude that is sufficient to cause the transistor TrC to enter the OFF state, for example. For example, when the transistor TrC is an NMOS transistor, the voltage V_{ON} is larger than the voltage V_{OFF}. For example, when the transistor TrC is a PMOS transistor, the voltage V_{ON} is smaller than voltage V_{OFF}.

In addition, when the read operation is performed, one of the plurality of word lines WL0 to WL2 is selected. In the illustrated example, the word line WL0 is selected. When selecting the word lines WL0 to WL2, for example, a voltage V_{ON}′ is applied to the word line select line LW0a corresponding to the word line WL0 as a target of the read operation among the plurality of word line select lines LW0a, LW1a, LW2a, and a voltage V_{OFF}′ is applied to the other word line select lines LW1a LW2a. In addition, among the plurality of word line select lines LW0b, LW1b, LW2b, the voltage V_{OFF}′ is applied to the word line select line LW0b corresponding to the word line WL0 as a target of the read operation, and the voltage V_{ON}′ is applied to the other word line select lines LW1b LW2b.

The voltage V_{ON}′ has a magnitude that is sufficient to cause the transistors TrRa, TrRb to enter the ON state, for example. The voltage V_{OFF}′ has a magnitude that is sufficient to cause the transistors TrRa, TrRb to enter the OFF state, for example. For example, when the transistors TrRa, TrRb are the NMOS transistors, the voltage V_{ON}′ is larger than the voltage V_{OFF}′. Also, for example, when the transistors TrRa, TrRb are the PMOS transistors, the voltage V_{ON}′ is smaller than the voltage V_{OFF}′.

Here, the voltage V_{ON} is applied to the word line WL0 (hereinafter referred to as “selected word line WL0”) connected to the memory cell MC (hereinafter referred to as “selected memory cell MC”) as a target of the read operation via the transistor TrR0a. This causes the transistor TrC in the selected memory cell MC to enter the ON state. As a result, the voltage of the global bit line GBL changes or a current flows through the global bit line GBL. By detecting the change of the voltage or the current, it is possible to read data stored in the selected memory cell MC.

In addition, the voltage V_{OFF} is applied to the unselected word line WL0 corresponding to the memory layers ML1, ML2, ML3, which are different from the selected memory cell MC, via the transistors TrR1a, TrR2a, TrR3a. This causes the transistor TrC in the memory cell MC to enter the OFF state.

In addition, the voltage V_{OFF} is applied to the unselected word lines WL1, WL2 corresponding to the memory layers ML0, ML1, ML2, ML3 via the transistors TrRb connected to the word line select lines LW1b, LW2b. This causes the transistor TrC in the memory cell MC to enter the OFF state.

In the following description, an example in which the transistors TrC, TrRa, TrRb are all NMOS transistors is described.

### Structure

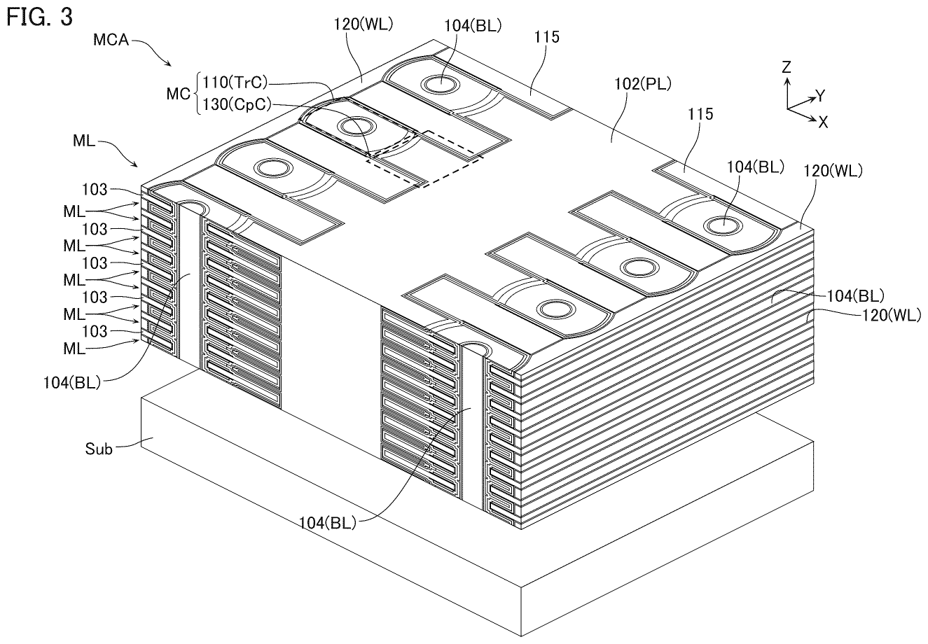

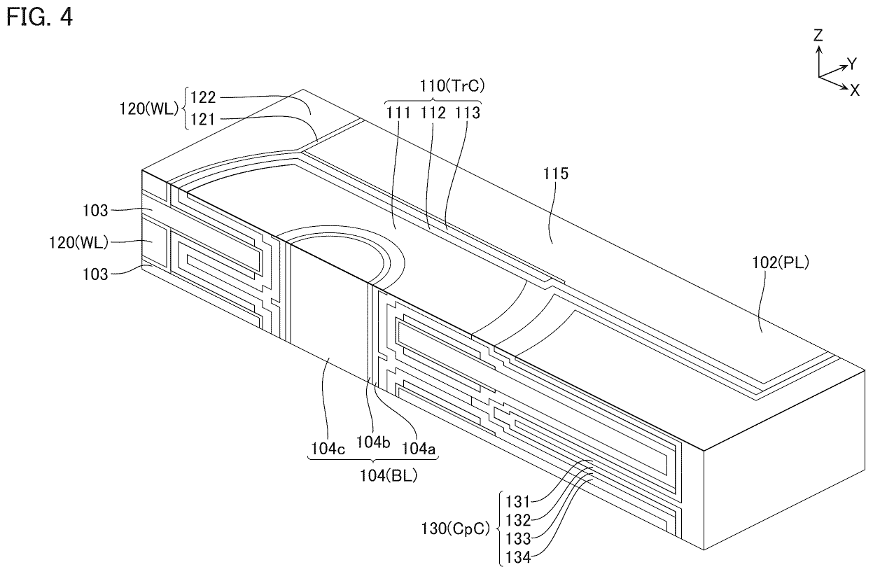

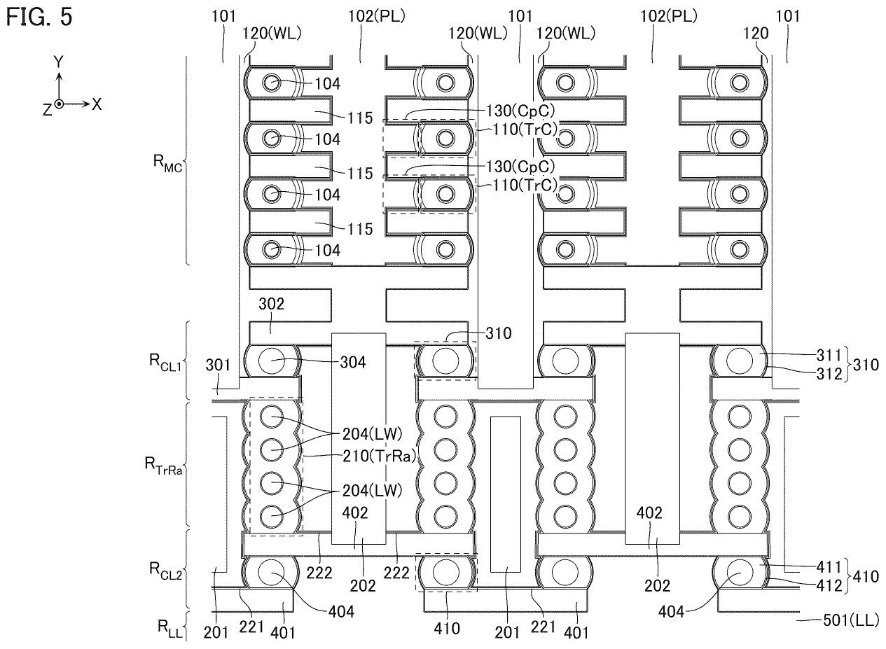

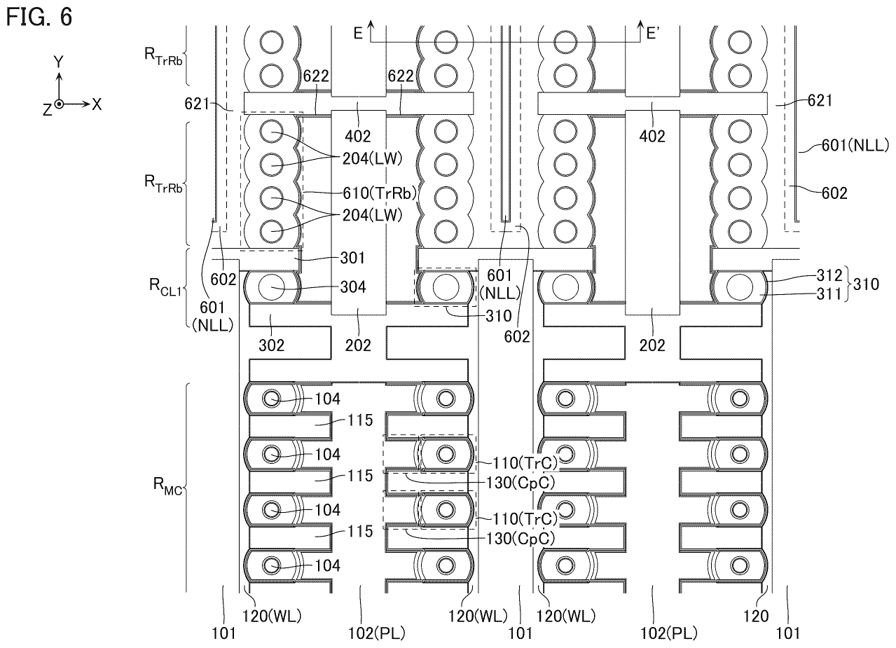

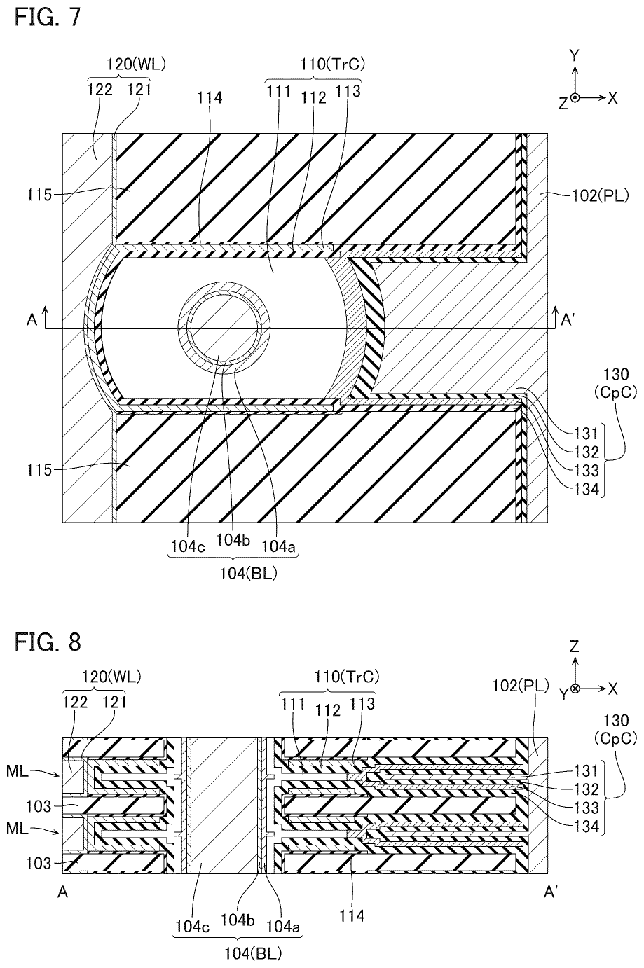

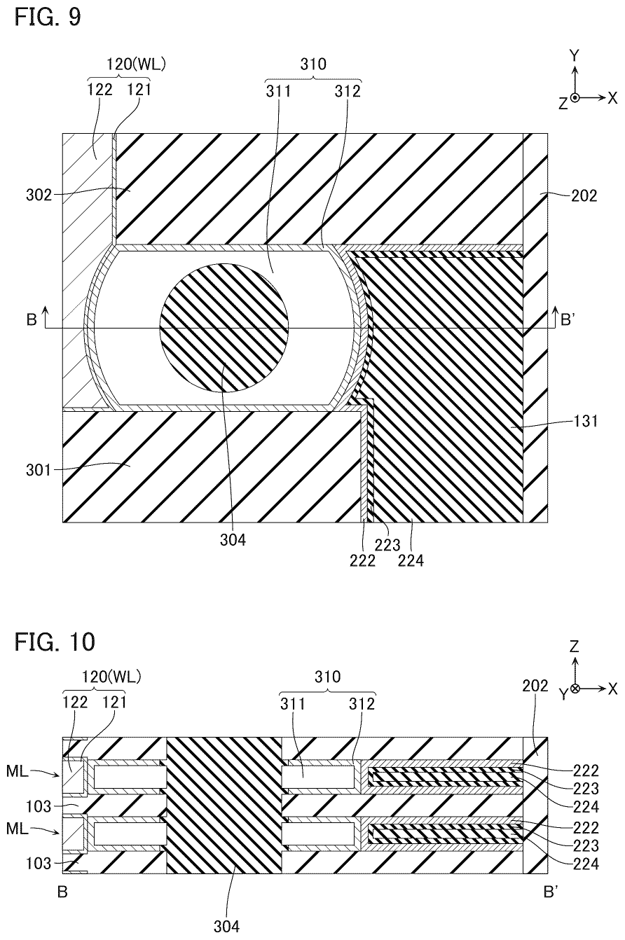

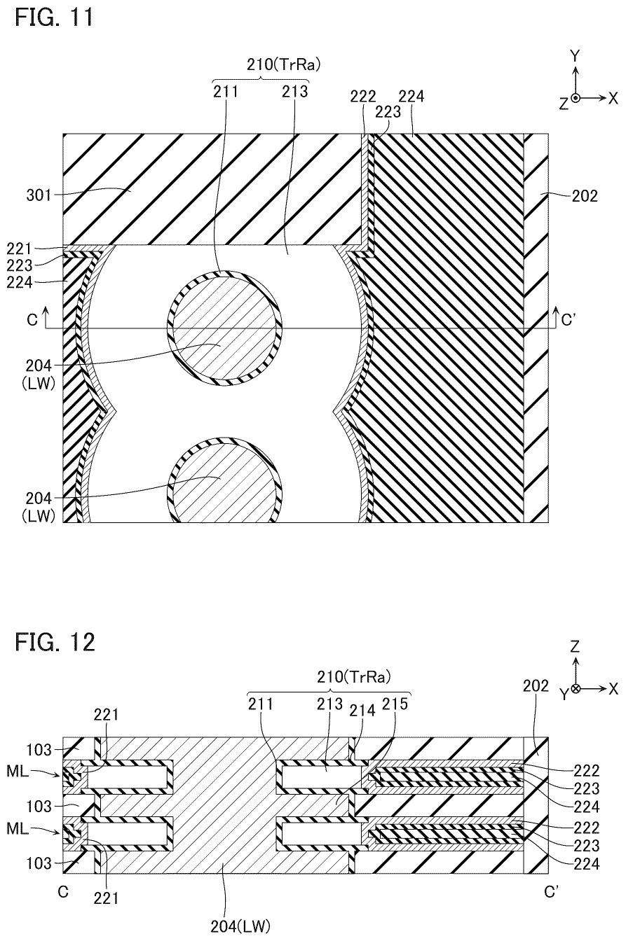

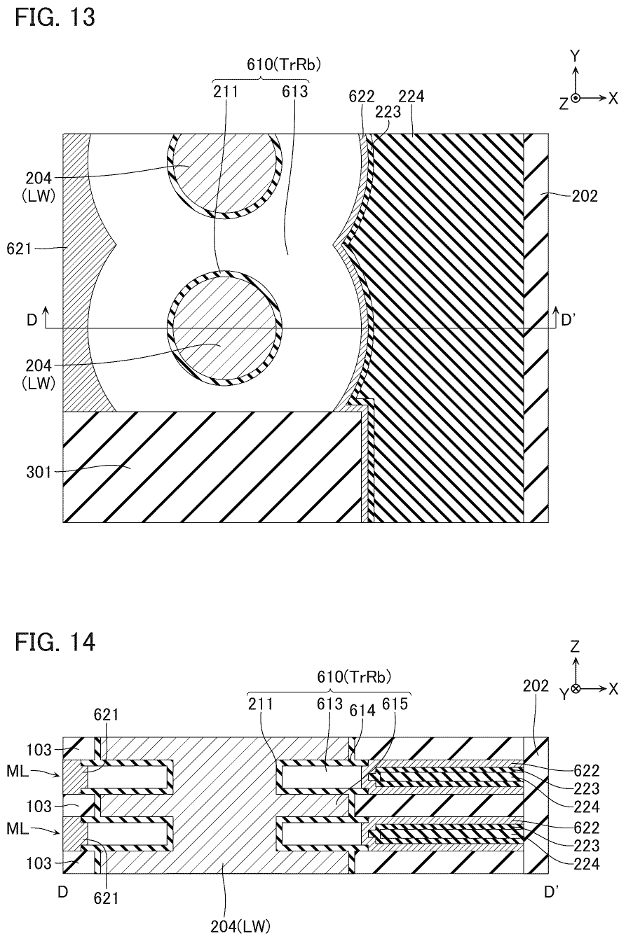

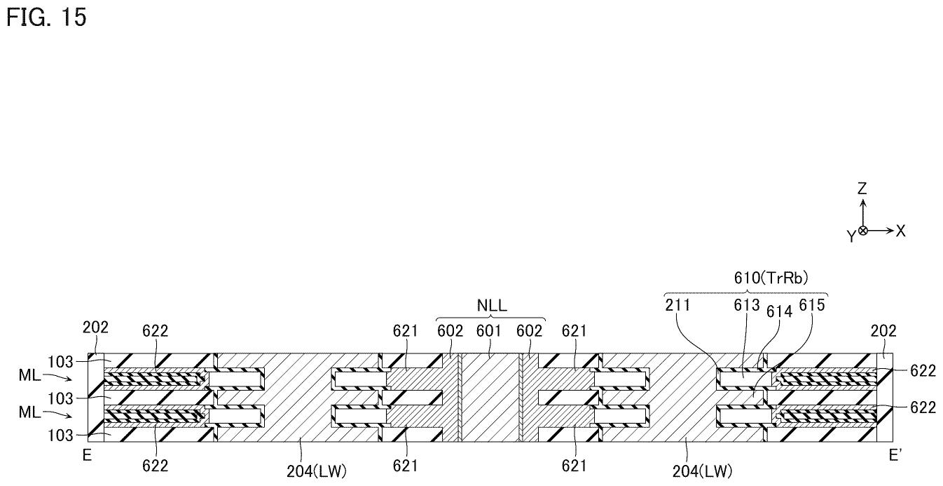

FIG. 3 is a schematic perspective view illustrating a configuration of a part of the semiconductor memory device according to the first embodiment. FIG. 4 is a schematic perspective view illustrating a configuration of a part of the semiconductor memory device and illustrates an enlarged part of FIG. 3. FIG. 5 and FIG. 6 are schematic X-Y cross-sectional views illustrating configurations of parts of the semiconductor memory device. FIG. 7, FIG. 9, and FIG. 11 are schematic X-Y cross-sectional views illustrating configurations of parts of the semiconductor memory device and each illustrate an enlarged part of FIG. 5. FIG. 8 is a schematic cross-sectional view illustrating a configuration of a part of the semiconductor memory device, and illustrates the structure in FIG. 7 cut along the A-A′ line viewed in the direction of the arrow. FIG. 10 is a schematic cross-sectional view illustrating a configuration of a part of the semiconductor memory device, and illustrates the structure in FIG. 9 cut along the B-B′ line viewed in the direction of the arrow. FIG. 12 is a schematic cross-sectional view illustrating a configuration of a part of the semiconductor memory device, and illustrates the structure in FIG. 11 cut along the C-C′ line viewed in the direction of the arrow. FIG. 13 is a schematic X-Y cross-sectional view illustrating a configuration of a part of the semiconductor memory device and illustrates an enlarged part of FIG. 6. FIG. 14 is a schematic cross-sectional view illustrating a configuration of a part of the semiconductor memory device, and illustrates the structure in FIG. 13 cut along the D-D′ line viewed in the direction of the arrow. FIG. 15 is a schematic cross-sectional view illustrating a configuration of a part of the semiconductor memory device, and illustrates the structure in FIG. 6 cut along the E-E′ line viewed in the direction of the arrow.

FIG. 3 illustrates a part of a semiconductor substrate Sub and the memory cell array MCA provided above the semiconductor substrate Sub.

The semiconductor substrate Sub is, for example, a semiconductor substrate, such as silicon (Si), containing a p-type impurity, such as boron (B). An insulating layer and an electrode layer, which are not illustrated, are provided on an upper surface of the semiconductor substrate Sub. The upper surface of the semiconductor substrate Sub, the insulating layer and the electrode layer, which are not illustrated, constitute a peripheral circuit for controlling the semiconductor memory device according to the first embodiment. For example, a sense amplifier circuit is provided in a region directly below the memory cell array MCA. The sense amplifier circuit is electrically connected to the global bit line GBL. The sense amplifier circuit is capable of reading the data stored in the selected memory cell MC by detecting the change of the voltage or the current of the bit line BL in the read operation. The peripheral circuit includes a sequencer that executes the read operation and the like by applying a predetermined voltage at a predetermined timing to each wiring in the memory cell array MCA and each configuration in the sense amplifier circuit.

The memory cell array MCA includes a plurality of memory layers ML arranged in the Z-direction. In addition, each insulating layer 103, such as silicon oxide (SiO₂), is provided between the plurality of memory layers ML.

As illustrated in FIGS. 5 and 6, the memory cell array MCA has a memory cell region R_{MC}.

As illustrated in FIG. 5, the memory cell array MCA is provided with a transistor region R_{TrRa} provided on one side of the memory cell region R_{MC} in the Y-direction, and a wiring region R_{LL} provided on one side of the transistor region R_{TrRa} in the Y-direction. In addition, the memory cell array MCA has a connection wiring region R_{CL1} between the memory cell region R_{MC} and the transistor region R_{TrRa}, and a connection wiring region R_{CL2} between the transistor region R_{TrRa} and the wiring region R_{LL}.

As illustrated in FIG. 6, the memory cell array MCA has a transistor region R_{TrRb} provided on the other side of the memory cell region R_{MC} in the Y-direction. In addition, the memory cell array MCA has a connection wiring region R_{CL1} provided between the memory cell region R_{MC} and the transistor region R_{TrRb}.

### Structure of Memory Cell Region R_{MC}

As illustrated in FIG. 5, the memory cell region R_{MC} is provided with a plurality of insulating layers 101 arranged in the X-direction, and a conductive layer 102 provided between two insulating layers 101 adjacent to one another in the X-direction. The insulating layers 101 and the conductive layers 102 extend in the Y-direction and the Z-direction, and divide the plurality of memory layers ML in the X-direction.

The insulating layer 101 includes, for example, silicon oxide (SiO₂).

The conductive layer 102 includes, for example, a stacked structure of titanium nitride (TiN) and silicon germanium (SiGe). The conductive layer 102 functions as a plate line PL (FIG. 1), for example.

In addition, a region between the insulating layer 101 and the conductive layer 102 in the memory cell region R_{MC} are provided with a plurality of via-wirings 104 arranged in the Y-direction. These plurality of via-wirings 104 each extend in the Z-direction, penetrating the plurality of memory layers ML, as illustrated in FIG. 3, for example.

As illustrated in FIG. 4, the via-wiring 104 contains, for example, a conductive oxide film 104a containing a conductive oxide, a barrier conductive film 104b, such as titanium nitride (TiN), and a conductive member 104c, such as tungsten (W). In addition, the via-wiring 104 may contain ruthenium (Ru), iridium (Ir), or another metal instead of the conductive oxide film 104a. The via-wiring 104 may also contain only an conductive oxide, or only ruthenium (Ru), iridium (Ir), or another metal.

In this specification, the “conductive oxide” includes, for example, indium oxide (ITO), indium zinc oxide (IZO), ruthenium oxide (RuO2), iridium oxide (IrO2), or another oxygen-containing conductive material.

The conductive member 104c has an approximately cylindrical shape extending in the Z-direction. The barrier conductive film 104b has an approximately hollow cylindrical shape extending in the Z-direction along an outer peripheral surface of the conductive member 104c. The conductive oxide film 104a has an approximately hollow cylindrical shape extending in the Z-direction along an outer peripheral surface of the barrier conductive film 104b. The via-wiring 104 functions as, for example, the bit line BL (FIG. 1).

The memory layer ML includes a conductive layer 120 provided between the insulating layer 101 and the plurality of via-wirings 104 and extending in the Y-direction, a plurality of transistor structures 110 arranged in the Y-direction corresponding to the plurality of via-wirings 104, and a plurality of capacitor structures 130 provided between the conductive layer 102 and the plurality of transistor structures 110, and arranged in the Y-direction corresponding to the plurality of via-wirings 104.

As illustrated in FIG. 4, the transistor structure 110 includes, for example, a semiconductor layer 111 connected to an outer peripheral surface of the via-wiring 104 and extending in the X-direction, an insulating layer 112 provided on an upper surface, a lower surface, both side surfaces of the semiconductor layer 111 in the Y-direction, and a side surface on one side (a conductive layer 120 side) of the semiconductor layer 111 in the X-direction, and a conductive layer 113 provided on an upper surface, a lower surface, both side surfaces of the insulating layer 112 in the Y-direction, and a side surface on one side (the conductive layer 120 side) of the insulating layer 112 in the X-direction.

In the X-Y cross section illustrated in FIG. 7, each of both side surfaces of the semiconductor layer 111 in the X-direction may be formed along a circle centered on the center position of the via-wiring 104. Similarly, each of the side surfaces on one side (the conductive layer 120 side) of the insulating layer 112 and the conductive layer 113 in the X-direction may also be formed along a circle centered on the center position of the via-wiring 104. In addition, both side surfaces of the semiconductor layer 111, the insulating layer 112, and the conductive layer 113 in the Y-direction may be formed in a straight line along a side surface of the insulating layer 115.

Furthermore, both side surfaces of the semiconductor layer 111 in the X-direction do not have to be formed along a circle. Even in such a case, for example, both side surfaces of the semiconductor layer 111 in the X-direction may be curved when viewed from the Z-direction. For example, a length of the semiconductor layer 111 in the X-direction may differ depending on a position in the Y-direction. For example, a length of the semiconductor layer 111 in the X-direction at a position close to the insulating layer 115 may be shorter than a length of the semiconductor layer 111 in the X-direction at a position far from the insulating layer 115.

The semiconductor layer 111 functions as, for example, a channel region of the transistor TrC (FIG. 1). The semiconductor layer 111 may be, for example, a semiconductor containing at least one element of gallium

(Ga) or aluminum (Al), and containing indium (In), zinc (Zn), and oxygen (O), or may be another oxide semiconductor. The plurality of semiconductor layers 111 arranged in the Z-direction are connected in common to the via-wiring 104 extending in the Z-direction.

The insulating layer 112 functions as, for example, a gate insulating film of the transistor TrC (FIG. 1). The insulating layer 112 includes, for example, silicon oxide (SiO₂) and the like.

The conductive layer 113 functions as, for example, the gate electrode of the transistor TrC (FIG. 1). The conductive layer 113 contains, for example, a conductive oxide, such as titanium nitride (TiN) or indium tin oxide (ITO). As illustrated in FIG. 5, the plurality of conductive layers 113 arranged in the Y-direction are connected in common to the conductive layer 120 extending in the Y-direction. As illustrated in FIGS. 7 and 8, the conductive layer 113 is opposed to an upper surface and a lower surface of the semiconductor layer 111, both side surfaces of the semiconductor layer 111 in the Y-direction, and a side surface of the semiconductor layer 111 on one side (the conductive layer 120 side) in the X-direction across the insulating layer 112.

As illustrated in FIG. 5, an insulating layer 115, such as silicon oxide (SiO₂), is provided between two semiconductor layers 111 adjacent to one another in the Y-direction. The insulating layer 115 extends in the Z-direction penetrating the plurality of memory layers ML.

The conductive layer 120 functions as the word line WL (FIG. 1), for example. As described above, the conductive layer 120 extends in the Y-direction. Each side surface on one side of the conductive layer 120 in the X-direction is connected to the plurality of conductive layers 113 arranged in the Y-direction. As illustrated in FIGS. 7 and 8, the conductive layer 120 includes a barrier conductive film 121 of, for example, titanium nitride (TiN) and a conductive film 122 of tungsten (W).

As illustrated in FIGS. 7 and 8, the capacitor structure 130, for example, includes a conductive layer 131, an insulating layer 132 provided on an upper surface and a lower surface of the conductive layer 131, both side surfaces of the conductive layer 131 in the Y-direction, and a side surface on one side (a transistor structure 110 side) of the conductive layer 131 in the X-direction, a conductive layer 133 provided on an upper surface and a lower surface of the insulating layer 132, both side surfaces of the insulating layer 132 in the Y-direction, and a side surface on one side (the transistor structure 110 side) of the insulating layer 132 in the X-direction, and an insulating layer 134 provided on an upper surface and a lower surface of the conductive layer 133, and both side surfaces of the conductive layer 133 in the Y-direction.

The conductive layer 131 functions as one of the electrodes of the capacitor CpC (FIG. 1). The conductive layer 131 includes, for example, a stacked structure of titanium nitride (TiN) and silicon germanium (SiGe). The conductive layer 131 is connected to the conductive layer 102.

The insulating layer 132 functions as an insulating layer of the capacitor CpC (FIG. 1). The insulating layer 132 may be, for example, zirconia (ZrO2), alumina (A12O3), or another insulating metal oxide. The insulating layer 132 may also be, for example, a stacked film of a plurality of insulating metal oxides (for example, a stacked film of zirconia and alumina).

The conductive layer 133 functions as, for example, the other electrode of the capacitor CpC (FIG. 1). The conductive layer 133 contains, for example, a conductive oxide, such as indium tin oxide (ITO). The conductive layer 133 is insulated from the conductive layer 131 via the insulating layer 132. The conductive layer 133 is connected to one side (the conductive layer 102 side) of the semiconductor layer 111 in the X-direction.

The insulating layer 134 includes, for example, silicon oxide (SiO₂). In the illustrated example, the insulating layer 134 is continuous with the insulating layer 112.

### Structure of Transistor Region R_{TrRa}

As illustrated in FIG. 5, the transistor region R_{TrRa} is provided with a plurality of insulating layers 201 arranged in the X-direction corresponding to the plurality of insulating layers 101, and an insulating layer 202 provided between two insulating layers 201 adjacent in the X-direction. The insulating layers 201, 202 extend in the Y-direction and the Z-direction and divide the plurality of memory layers ML in the X-direction. The insulating layer 201 and the insulating layer 202 include, for example, silicon oxide (SiO₂).

In addition, a region between the insulating layer 201 and the insulating layer 202 in the transistor region R_{TrRa} are provided with a plurality of via-wirings 204. The plurality of via-wirings 204 are arranged in the Y-direction and extend in the Z-direction, penetrating the plurality of memory layers ML, as illustrated in FIG. 12, for example.

The via-wiring 204 includes, for example, a stacked structure of titanium nitride (TiN) and tungsten (W). The via-wiring 204 has an approximately cylindrical shape extending in the Z-direction.

The plurality of via-wirings 204 arranged in the Y-direction functions as, for example, one word line select line LW (FIG. 1). The plurality of word line select lines LW are provided corresponding to the plurality of word lines WL included in the memory layer ML, as illustrated in FIG. 1, for example.

The memory layer ML includes a part of a plurality of transistor structures 210 provided corresponding to the plurality of conductive layers 120, a conductive layer 221 provided between the transistor structure 210 and the insulating layer 201, and a conductive layer 222 provided between the transistor structure 210 and the insulating layer 202.

The transistor structure 210 includes a part provided in the memory layer ML and parts provided at height positions corresponding to the insulating layers 103, as illustrated in FIG. 12. Among these, the part provided in the memory layer ML includes a plurality of insulating layers 211 provided on outer peripheral surfaces of the plurality of via-wirings 204, and a semiconductor layer 213 provided on outer peripheral surfaces of these plurality of insulating layers 211 and extending in the Y-direction, as illustrated in FIG. 11. In addition, the parts provided at the height positions corresponding to the insulating layers 103 include insulating layers 214 provided on an upper surface and a lower surface of the semiconductor layer 213, and conductive layers 215 provided on an upper surface and a lower surface of the insulating layers 214, as illustrated in FIG. 12.

In an X-Y cross section illustrated in FIG. 11, side surfaces of the semiconductor layer 213 on both side in the X-direction may be formed along a plurality of circles overlapping with one another, with the center positions of the plurality of via-wirings 204 as the centers.

The insulating layer 211 includes, for example, silicon oxide (SiO₂). The insulating layer 211 has an approximately hollow cylindrical shape extending in the Z-direction along a part of the outer peripheral surface of the via-wiring 204. The insulating layer 211 is continuous with the insulating layer 214 (FIG. 12).

The semiconductor layer 213 functions as, for example, the channel region of the transistor TrRa (FIG. 1). The semiconductor layer 213 may be a semiconductor containing at least one element of gallium (Ga) or aluminum (Al), and containing indium (In), zinc (Zn), and oxygen (O), or it may be another oxide semiconductor.

The insulating layer 214 functions as, for example, the gate insulating film of the transistor TrRa (FIG. 1). The insulating layer 214 includes, for example, silicon oxide (SiO₂) and the like.

The conductive layer 215 functions as, for example, the gate electrode of the transistor TrRa (FIG. 1). The conductive layer 215 includes, for example, a stacked structure of titanium nitride (TiN) and tungsten (W). The conductive layer 215 is connected to the plurality of via-wirings 204 arranged in the Y-direction. When focusing on two semiconductor layers 213 adjacent to one another in the Z-direction, one conductive layer 215 provided between the two semiconductor layers 213 is opposed to a lower surface of the semiconductor layer 213 provided thereabove and an upper surface of the semiconductor layer 213 provided therebelow, via the insulating layer 214. The plurality of conductive layers 215 arranged in the Z-direction are connected in common to the via-wiring 204 extending in the Z-direction.

When focusing on two conductive layers 215 adjacent to one another in the Z-direction, these conductive layers 215 are connected only via the via-wiring 204. In other words, both end portions of these two conductive layers 215 in the Y-direction are spaced in the Z-direction. Similarly, both end portions of these two conductive layers 215 in the X-direction are also spaced in the Z-direction.

The conductive layer 221 is connected to one side (an insulating layer 201 side) of the semiconductor layer 213 in the X-direction. As illustrated in FIG. 5, the conductive layer 221 extends in the Y-direction from the transistor region R_{TrRa} to the connection wiring region R_{CL2}, and has a function of electrically connecting the above-described other electrode of the transistor TrRa (FIG. 1) and the layer select line LL (FIG. 1). The conductive layer 221 contains, for example, a conductive oxide. In addition, the conductive layer 221 may contain ruthenium (Ru), iridium (Ir), or another metal instead of the conductive oxide. The conductive layer 221 may contain only the conductive oxide, or may contain only ruthenium (Ru), iridium (Ir), or another metal.

As illustrated in FIG. 12, the conductive layer 221 may include, for example, a part formed on a lower surface of the insulating layer 103, a part formed on an upper surface of the insulating layer 103, and a part formed on a side surface of the semiconductor layer 213 on one side (the insulating layer 201 side) in the X-direction. In addition, a region surrounded by the conductive layer 221 may be provided with insulating layers 223, 224, such as silicon oxide (SiO₂).

The conductive layer 222 is connected to the semiconductor layer 213. As illustrated in FIG. 5, the conductive layer 222 extends in the Y-direction from the transistor region R_{TrRa} to the connecting wiring region R_{CL1}, and has a function of electrically connecting the above-described one electrode of the transistor TrRa (FIG. 1) to the word line WL (FIG. 1). The conductive layer 222 contains, for example, a conductive oxide. The conductive layer 222 may also include ruthenium (Ru), iridium (Ir), or another metal instead of the conductive oxide. In addition, the conductive layer 222 may contain only the conductive oxide, or may contain only ruthenium (Ru), iridium (Ir), or another metal.

As illustrated in FIG. 12, the conductive layer 222 may include, for example, a part formed on lower surfaces of the insulating layers 103, 214, a part formed on upper surfaces of the insulating layers 103, 214, and a part formed on a side surface of the semiconductor layer 213 on the other side (an insulating layer 202 side) in the X-direction. In addition, a region surrounded by the conductive layer 222 may have the insulating layers 223, 224, such as silicon oxide (SiO₂).

### Structure of Connection Wiring Region R_{CL1}

As illustrated in FIG. 5, the connection wiring region R_{CL1} includes insulating layers 301, 302 arranged in the Y-direction. The insulating layer 301 is connected to an end portion of the insulating layer 101 in the Y-direction. The insulating layer 302 is provided on a side of the memory cell region R_{MC} with respect to the insulating layer 301. The insulating layer 302 is connected to an end portion of the insulating layer 202 in the Y-direction. The insulating layers 301, 302 extend in the X-direction and the Z-direction, and divide the plurality of memory layers ML in the Y-direction. The insulating layer 301 and the insulating layer 302 include, for example, silicon oxide (SiO₂).

In addition, in the connection wiring region R_{CL1}, an insulating layer 304, such as silicon oxide (SiO₂), is provided in a region between the insulating layer 301 and the insulating layer 302. The insulating layer 304 extends in the Z-direction penetrating the plurality of memory layers ML, as illustrated in FIG. 10, for example.

The memory layer ML includes a plurality of connection wiring portions 310 provided corresponding to the plurality of conductive layers 120.

As illustrated in FIG. 9, the connection wiring portion 310 includes, for example, a semiconductor layer 311, such as silicon (Si), provided on an outer peripheral surface of the insulating layer 304, and a conductive layer 312 provided on an upper surface, a lower surface, and an outer peripheral surface of the semiconductor layer 311.

In the X-Y cross section illustrated in FIG. 9, side surfaces of the semiconductor layer 311 and the conductive layer 312 on both sides in the X-direction may be formed along a circle centered on the center position of the insulating layer 304. In addition, side surfaces of the semiconductor layer 311 and the conductive layer 312 on both sides in the Y-direction may be formed in a straight line along side surfaces of the insulating layers 301, 302 in the Y-direction.

A side surface of the conductive layer 312 on one side in the X-direction is connected to the conductive layer 120. A side surface of the conductive layer 312 on the other side in the X-direction is connected to the conductive layer 222. The conductive layer 312 has a function of electrically connecting the above-described one electrode of the transistor TrRa (FIG. 1) to the word line WL (FIG. 1).

### Structure of Connection Wiring Region R_{CL2}

As illustrated in FIG. 5, the connection wiring region R_{CL2} includes insulating layers 401, 402 arranged in the Y-direction. The insulating layer 402 is arranged on a side of the memory cell region R_{MC} with respect to the insulating layer 401. The insulating layer 402 is connected to an end portion of the insulating layer 202 in the Y-direction. The insulating layers 401, 402 extend in the X-direction and the Z-direction, and divide the plurality of memory layers ML in the Y-direction. The insulating layer 401 and the insulating layer 402 include, for example, silicon oxide (SiO₂).

In addition, in the connection wiring region R_{CL2}, an insulating layer 404, such as silicon oxide (SiO₂), is provided in a region between the insulating layer 401 and the insulating layer 402. The insulating layer 404 extends in the Z-direction penetrating the plurality of memory layers ML.

The memory layer ML includes a plurality of connection wiring portions 410 provided corresponding to the plurality of conductive layers 120.

The connection wiring portion 410 includes a semiconductor layer 411, such as silicon (Si), provided on an outer peripheral surface of the insulating layer 404, and a conductive layer 412 provided on an upper surface, a lower surface, and an outer peripheral surface of the semiconductor layer 411.

In an X-Y cross section illustrated in FIG. 5, side surfaces of the semiconductor layer 411 and the conductive layer 412 on both sides in the X-direction may be formed along a circle having the center position of the insulating layer 404 as the center. In addition, side surfaces of the semiconductor layer 411 and the conductive layer 412 on both sides in the Y-direction may be formed in a straight line along side surfaces of the insulating layers 401, 402 in the Y-direction.

A side surface of the conductive layer 412 on one side in the X-direction is connected to the conductive layer 221. A side surface of the conductive layer 412 on the other side in the X-direction is connected to a conductive layer 501 in the wiring region R_{LL}. The conductive layer 412 has a function of electrically connecting the above-described other electrode of the transistor TrRa (FIG. 1) and the layer select line LL (FIG. 1).

### Structure of Wiring Region R_{LL}

The memory layer ML includes the conductive layer 501 extending in the X-direction. The conductive layer 501 functions as, for example, a layer select line LL (FIG. 1). The conductive layer 501 is connected to the respective plurality of conductive layers 412 arranged in the X-direction. The conductive layer 501 includes, for example, a stacked structure of titanium nitride (TiN) and tungsten (W).

### Structure of Transistor Region R_{TrRb}

As illustrated in FIG. 6, the transistor region R_{TrRb} is provided with a plurality of conductive layers 601 arranged in the X-direction corresponding to the plurality of insulating layers 101, and conductive layers 602 provided on side surfaces of the conductive layer 601 in the X-direction and the Y-direction, and the insulating layer 202 provided between two conductive layers 601 adjacent to one another in the X-direction (or two conductive layers 602 adjacent to one another in the X-direction).

As illustrated in FIGS. 6 and 15, the conductive layers 601, 602 extend in the Y-direction and the Z-direction and divide the plurality of memory layers ML in the X-direction. The conductive layer 601 includes, for example, a stacked structure of titanium nitride (TiN) and tungsten (W). The conductive layer 602 contains, for example, a conductive oxide. The conductive layer 602 may also contain ruthenium (Ru), iridium (Ir), or another metal instead of the conductive oxide. In addition, the conductive layer 602 may contain only the conductive oxide, or may contain only ruthenium (Ru), iridium (Ir), or another metal. The conductive layers 601, 602 function as, for example, the wiring NLL (FIG. 1).

In addition, the transistor region R_{TrRb} is provided with a plurality of via-wirings 204 in regions between the conductive layers 601, 602 and the insulating layers 202. In other words, in the transistor region R_{TrRb}, the conductive layers 601, 602 and the insulating layer 202 are arranged with the plurality of via-wirings 204 in the X-direction.

The memory layer ML includes a part of a plurality of transistor structure 610 provided corresponding to the plurality of conductive layers 120, a conductive layer 621 provided between the transistor structure 610 and the conductive layer 601, and a conductive layer 622 provided between the transistor structure 610 and the insulating layer 202.

As illustrated in FIG. 14, the transistor structure 610 includes a part provided in the memory layer ML and parts provided at the height positions corresponding to the insulating layers 103. Among these, the part provided in the memory layer ML includes a plurality of insulating layers 211 provided on outer peripheral surfaces of the plurality of via-wirings 204, as illustrated in FIG. 13, and a semiconductor layer 613 provided on outer peripheral surfaces of these plurality of insulating layers 211 and extending in the Y-direction. In addition, the parts provided at the height positions corresponding to the insulating layers 103 include insulating layers 614 provided on an upper surface and a lower surface of the semiconductor layer 613, and conductive layers 615 provided on an upper surface and a lower surface of the insulating layer 614, as illustrated in FIG. 14.

The semiconductor layer 613, the insulating layer 614, and the conductive layer 615 are basically configured in the same way as the semiconductor layer 213, the insulating layer 214, and the conductive layer 215 (FIGS. 11 and 12). However, the semiconductor layer 613, the insulating layer 614, and the conductive layer 615 function as the channel region, the gate insulating film, and the gate electrode of the transistor TrRb (FIG. 1), respectively. In the transistor region R_{TrRb}, the conductive layers 601, 602 and the insulating layer 202 are arranged with the semiconductor layer 613, the insulating layer 614, and the conductive layer 615 in the X-direction.

The conductive layer 621 is connected to a side surface of the semiconductor layer 613 on one side (a conductive layer 601 side) in the X-direction. The conductive layer 621 is embedded in a region between two insulating layers 103 adjacent to one another in the Z-direction. As illustrated in FIGS. 6 and 15, the conductive layer 621 is connected to the conductive layer 602 and has a function of electrically connecting the above-described other electrode of the transistor TrRb (FIG. 1) and the wiring NLL (FIG. 1). The conductive layer 621 contains, for example, a conductive oxide. In addition, the conductive layer 621 may contain ruthenium (Ru), iridium (Ir), or another metal instead of the conductive oxide. The conductive layer 621 may also contain only the conductive oxide, or may contain only ruthenium (Ru), iridium (Ir), or another metal.

The conductive layer 622 is basically configured in the same way as the conductive layer 222. However, the conductive layer 622 is connected to the semiconductor layer 613. In addition, as illustrated in FIG. 6, the conductive layer 622 extends in the Y-direction from the transistor region R_{TrRb} to the connection wiring region R_{CL1}, and has a function of electrically connecting the above-described one electrode of the transistor TrRb (FIG. 1) and the word line WL (FIG. 1).

### Manufacturing Method

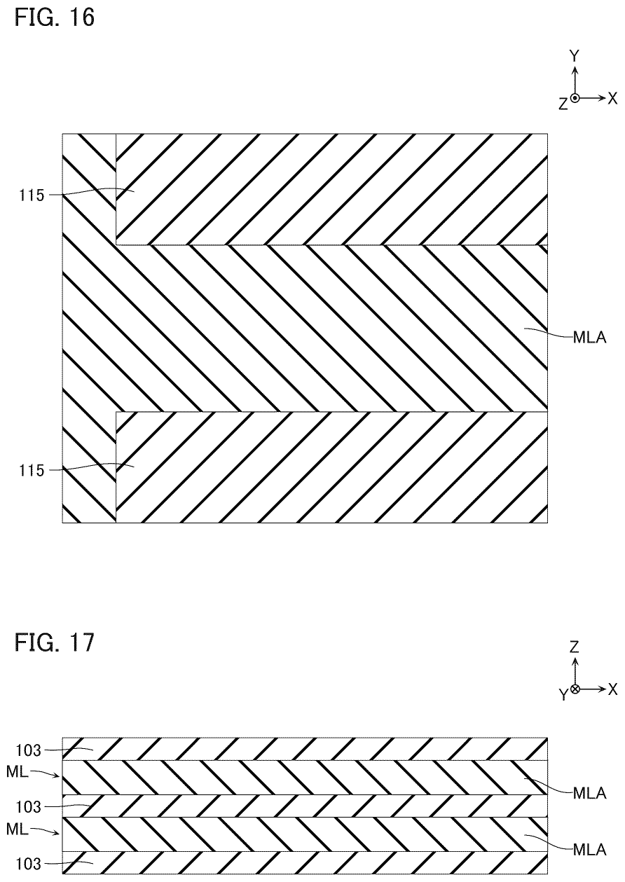

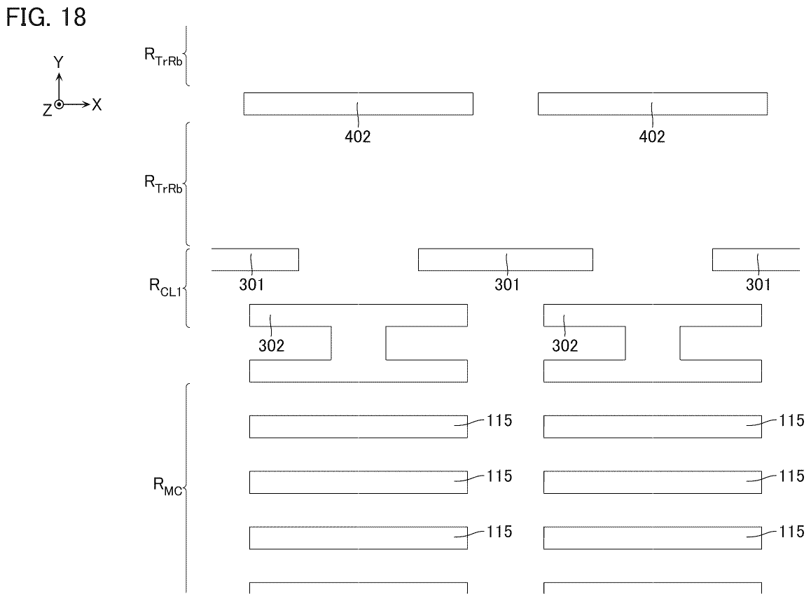

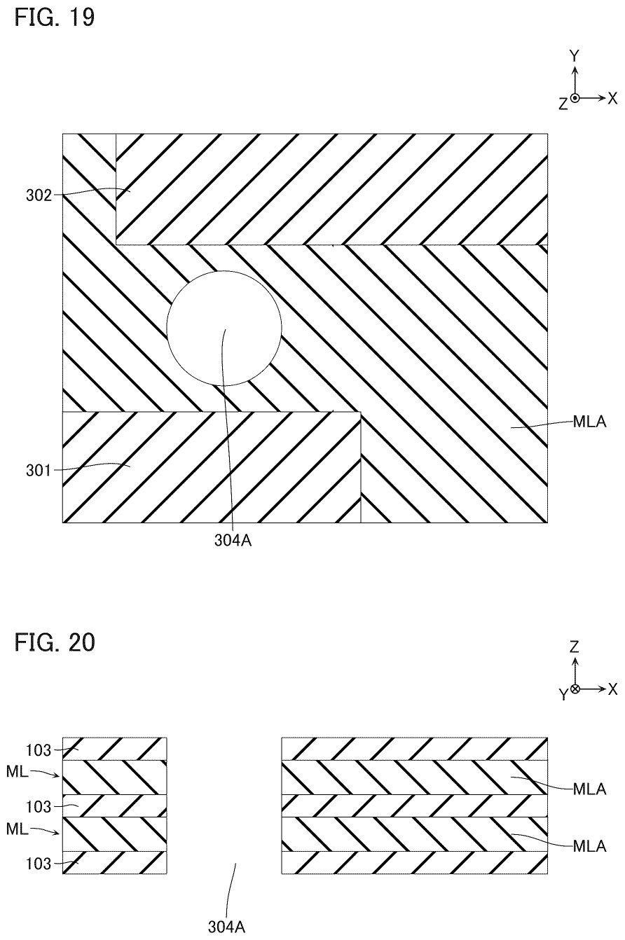

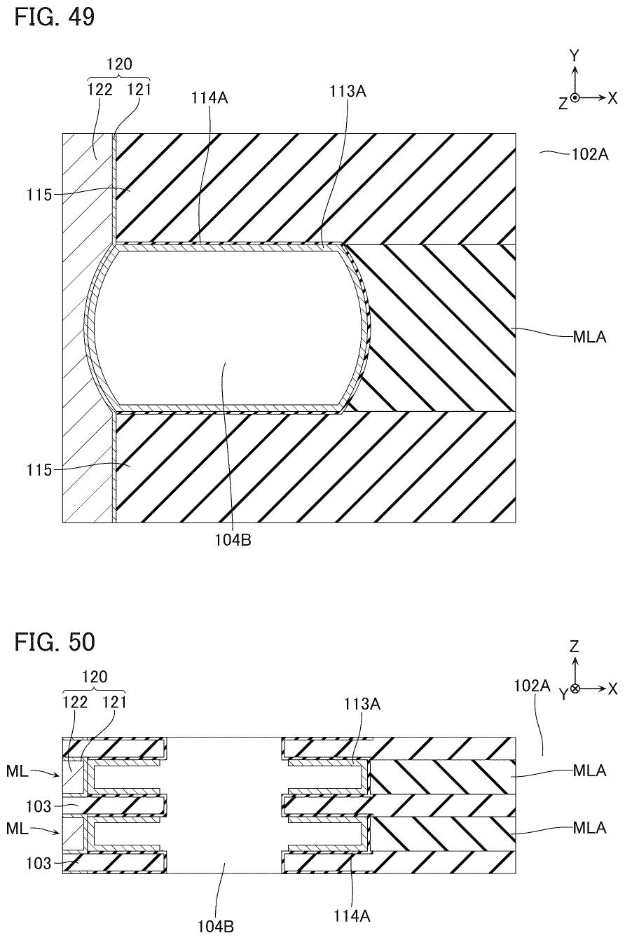

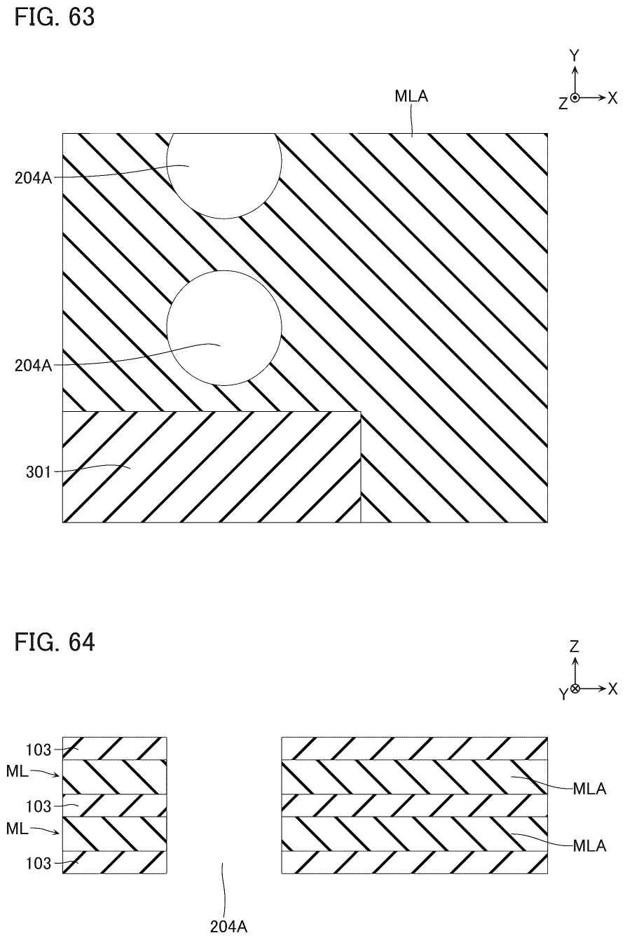

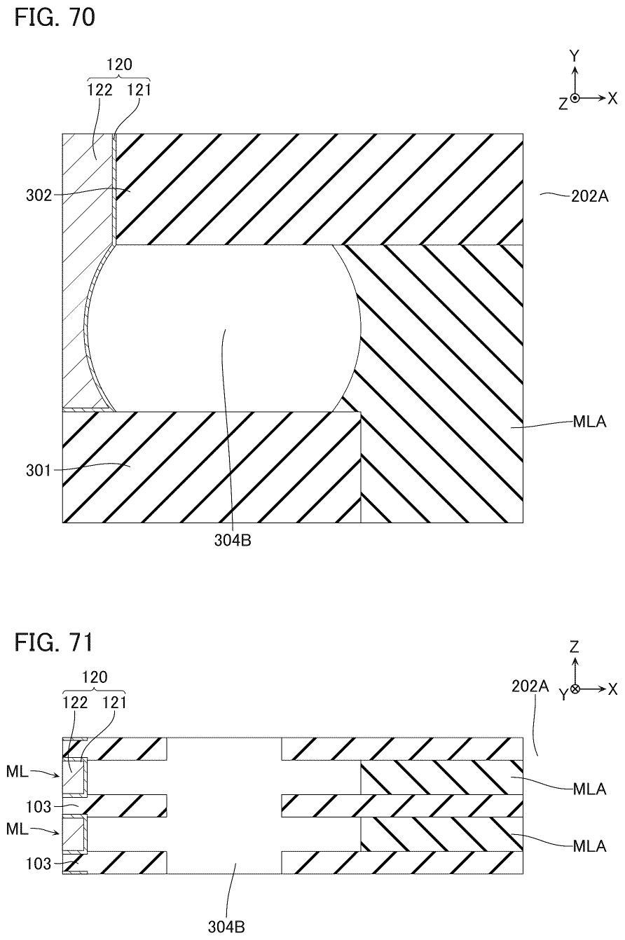

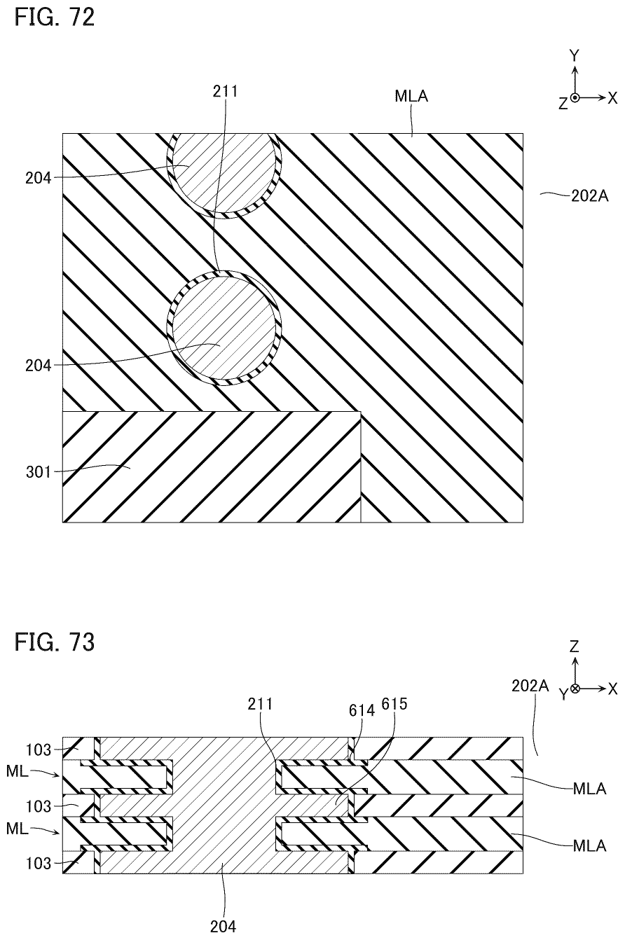

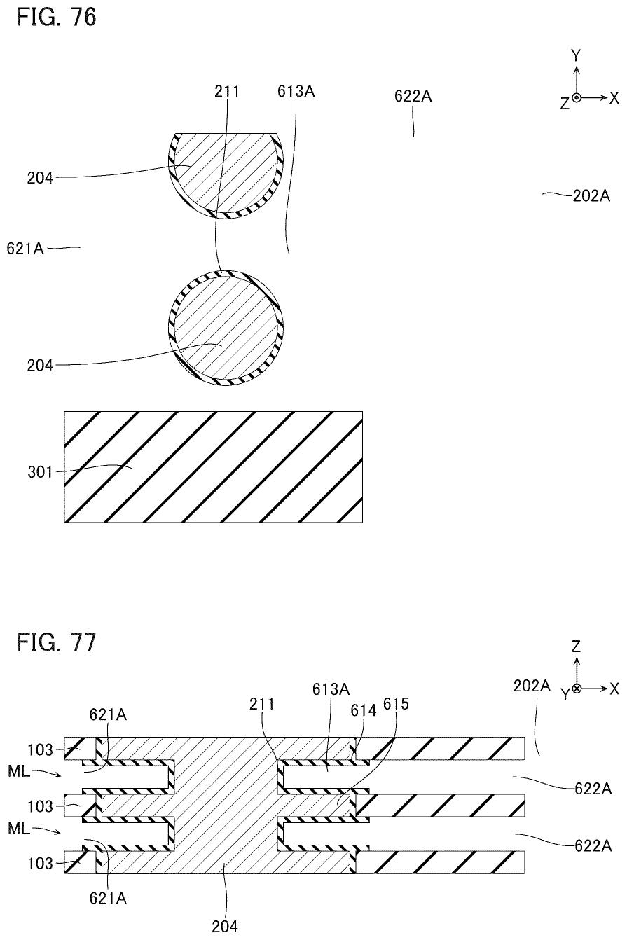

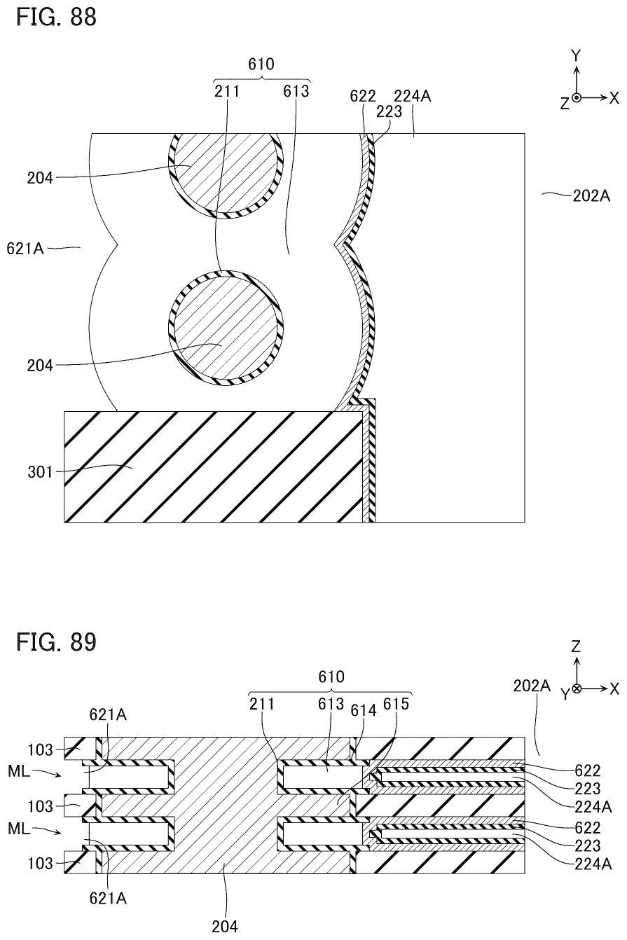

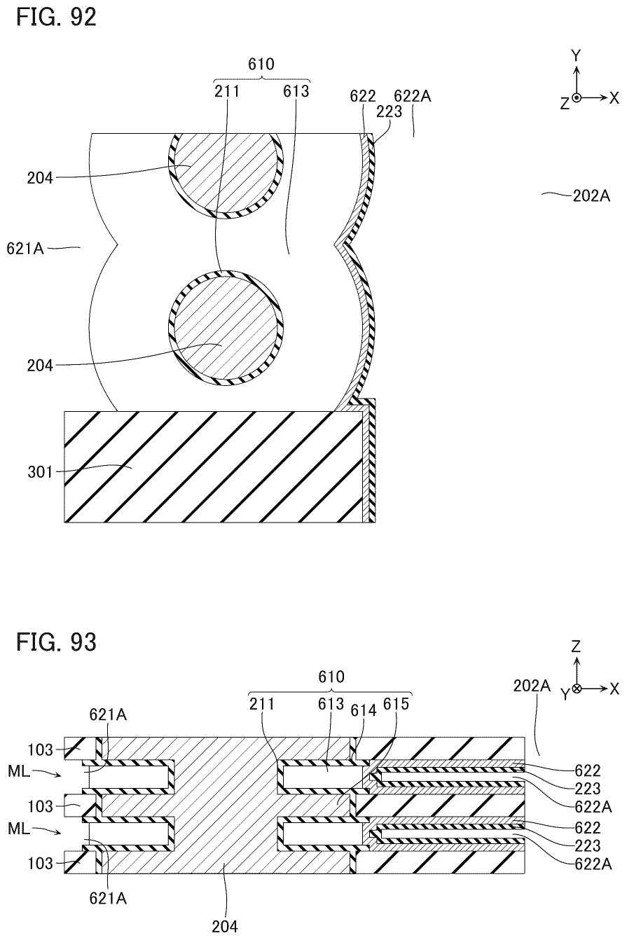

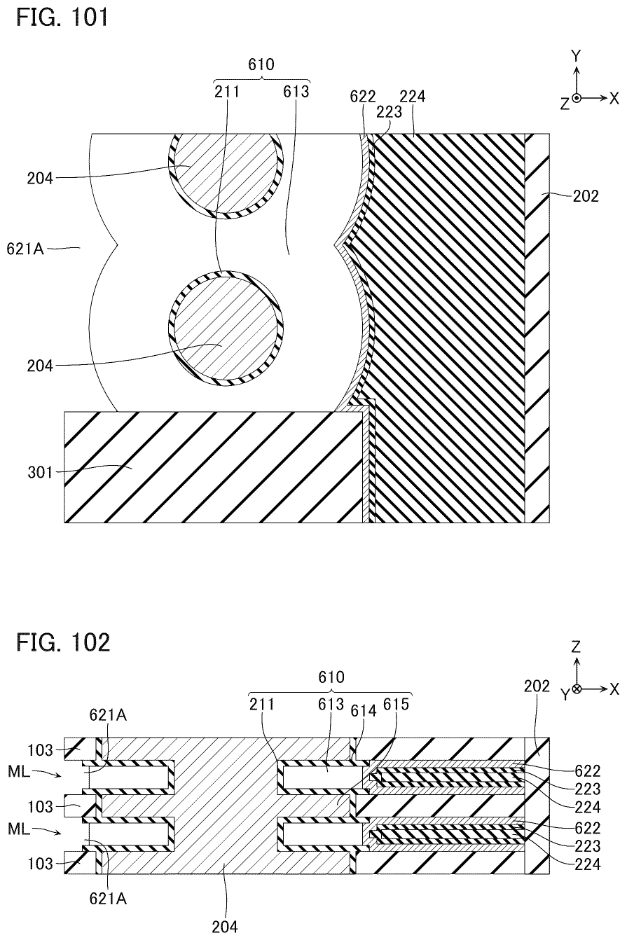

FIGS. 16 to 118 are schematic cross-sectional views for describing the manufacturing method of the semiconductor memory device of the first embodiment. FIGS. 16, 25, 27, 30, 32, 34, 37, 39, 42, 44, 46, 49, 51, 53, 55, 57, 59, 61, 103, 105, 107, 109, 111, 113, 115, and 117 illustrate the cross-sectional views corresponding to FIG. 7. FIGS. 17, 26, 28, 29, 31, 33, 35, 36, 38, 40, 43, 45, 47, 50, 52, 54, 56, 58, 60, 62, 104, 106, 108, 110, 112, 114, 116, and 118 illustrate the cross-sectional views corresponding to FIG. 8. FIGS. 18, 41, 48, and 69 illustrate the cross-sectional views corresponding to FIG. 6. FIGS. 19, 21, 23, 70, 74, 82, 86, 90, 94, 96, and 98 illustrate cross-sectional views corresponding to FIG. 9. FIGS. 20, 22, 24, 71, 75, 83, 87, 91, 95, 97, 99, and 100 illustrate cross-sectional views corresponding to FIG. 10. FIGS. 63, 67, 72, 76, 78, 80, 84, 88, 92, and 101 illustrate cross-sectional views corresponding to FIG. 13. FIGS. 64, 65, 66, 68, 73, 77, 79, 81, 85, 89, 93, and 102 illustrate cross-sectional views corresponding to FIG. 14.

In the same manufacturing method, for example, as illustrated in FIG. 17, the plurality of insulating layers 103 and a plurality of sacrifice layers MLA are alternately formed. The sacrifice layer MLA contains, for example, silicon nitride (Si₃N₄). This process is performed by chemical vapor deposition (CVD), for example.

Next, as illustrated in FIGS. 16 and 18, the insulating layers 115, 301, 302, 402 are formed. In addition, although it is omitted from the illustration, the insulating layers 401 (FIG. 5) are formed. In this process, for example, openings are formed at positions corresponding to the insulating layers 115, 301, 302, 401, 402. These openings extend in the X-direction and the Z-direction, and divide the plurality of insulating layers 103 and the plurality of sacrifice layers MLA arranged in the Z-direction, in the Y-direction. This process is performed by RIE or the like. After the openings are formed, the insulating layers 115, 301, 302, 401, 402 are formed. This process is performed by CVD, for example.

Next, as illustrated in FIGS. 19 and 20, an opening 304A is formed at a position corresponding to the insulating layer 304, for example. The opening 304A extends in the Z-direction and penetrates the plurality of insulating layers 103 and the plurality of sacrifice layers MLA arranged in the Z-direction as illustrated in FIG. 20. This process is performed by RIE or the like.

Although it is omitted from the illustration, the connection wiring portion 410 (FIG. 5) is formed in the same way as the connection wiring portion 310. For example, in this process, an opening similar to the opening 304A is formed at a position corresponding to the insulating layer 404 (FIG. 5). Similarly in the following processes, the process performed at a position corresponding to the connection wiring portion 310 is also performed at a position corresponding to the connection wiring portion 410.

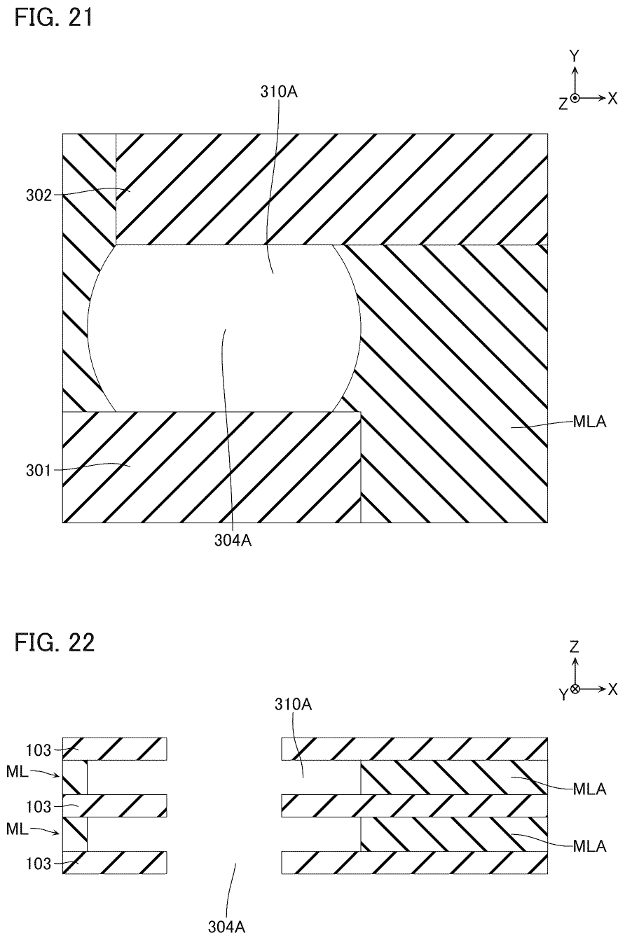

Next, for example, as illustrated in FIGS. 21 and 22, openings 310A are formed at positions corresponding to the connection wiring portions 310. Inside the opening 310A, a part of an upper surface and a part of a lower surface of the insulating layer 103, a part of a side surface of the sacrifice layer MLA in the X-direction, and parts of side surfaces of the insulating layers 301, 302 in the Y-direction are exposed. In this process, for example, parts of the sacrifice layers MLA are selectively removed through the opening 304A. This process is performed by wet etching, for example.

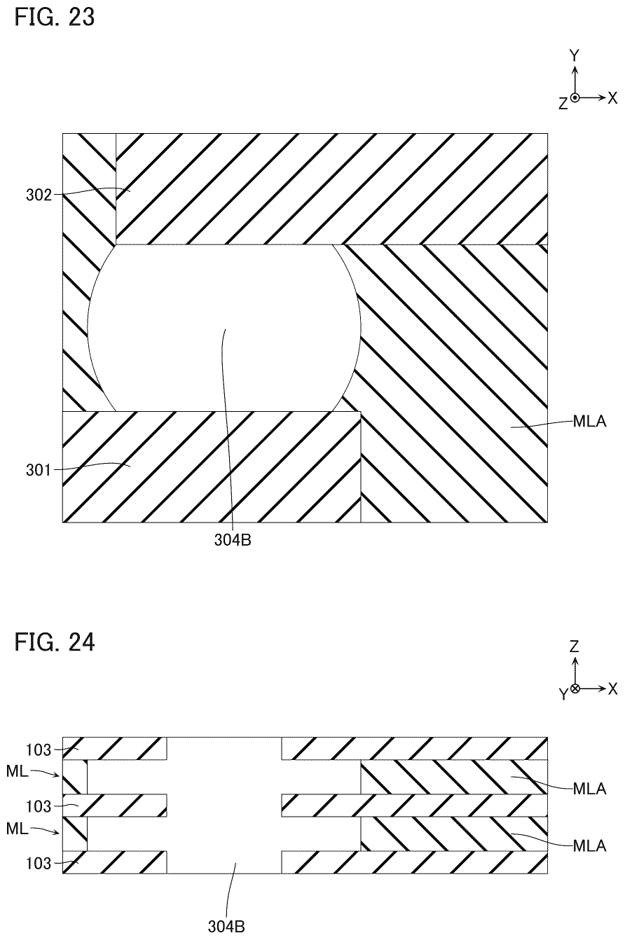

Next, as illustrated in FIGS. 23 and 24, for example, a sacrifice layer 304B, such as silicon (Si), is formed inside the opening 310A and the opening 304A. This process is performed by CVD, for example.

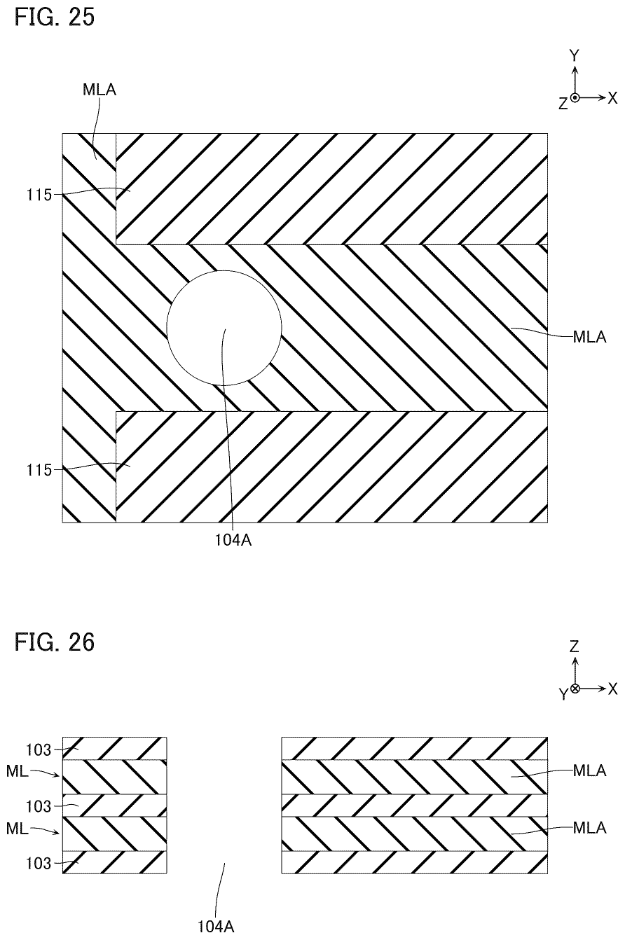

Next, as illustrated in FIGS. 25 and 26, an opening 104A is formed at a position corresponding to the via-wiring 104. The opening 104A extends in the Z-direction and penetrates the plurality of insulating layers 103 and the plurality of sacrifice layers MLA arranged in the Z-direction as illustrated in FIG. 26. This process is performed by RIE, for example.

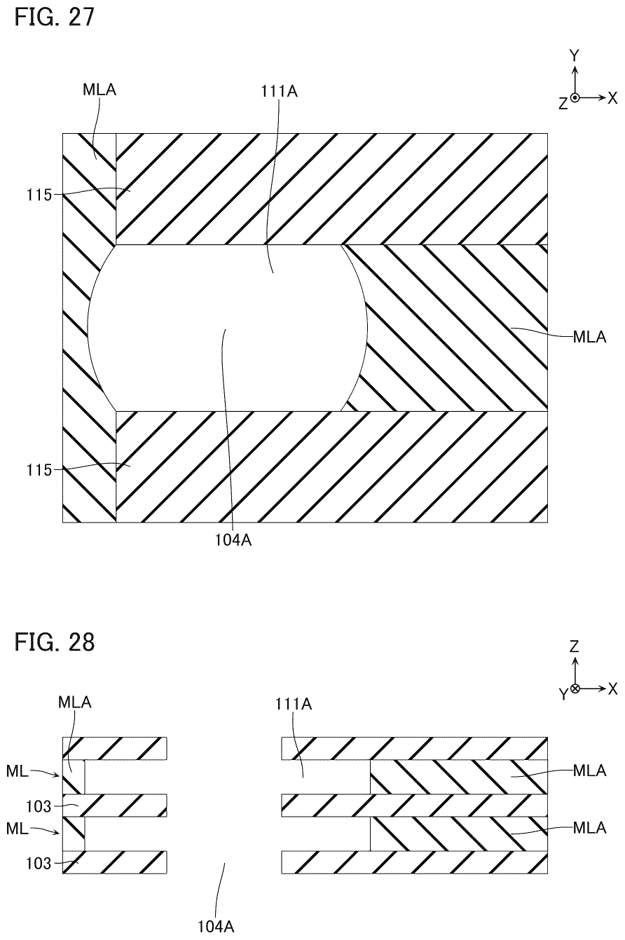

Next, as illustrated in FIGS. 27 and 28, for example, openings 111A are formed at positions corresponding to the semiconductor layers 111. Inside the opening 111A, a part of the upper surface and a part of the lower surface of the insulating layer 103, a part of a side surface of the sacrifice layer MLA in the X-direction, and a part of a side surface of the insulating layer 115 in the Y-direction are exposed. In this process, for example, parts of the sacrifice layers MLA are selectively removed through the opening 104A. This process is performed by wet etching, for example.

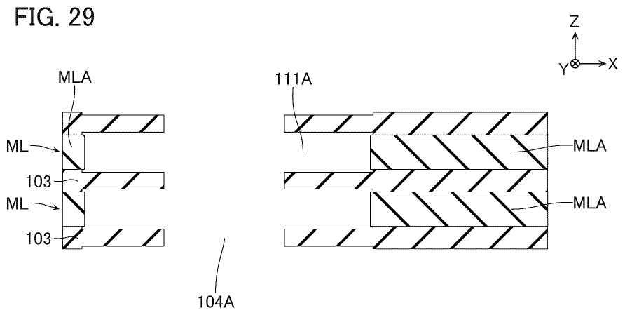

Next, for example, as illustrated in FIG. 29, parts of the insulating layers 103 are removed. In this process, widths of the openings 111A in the Z-direction are increased. This process is performed by wet etching, for example.

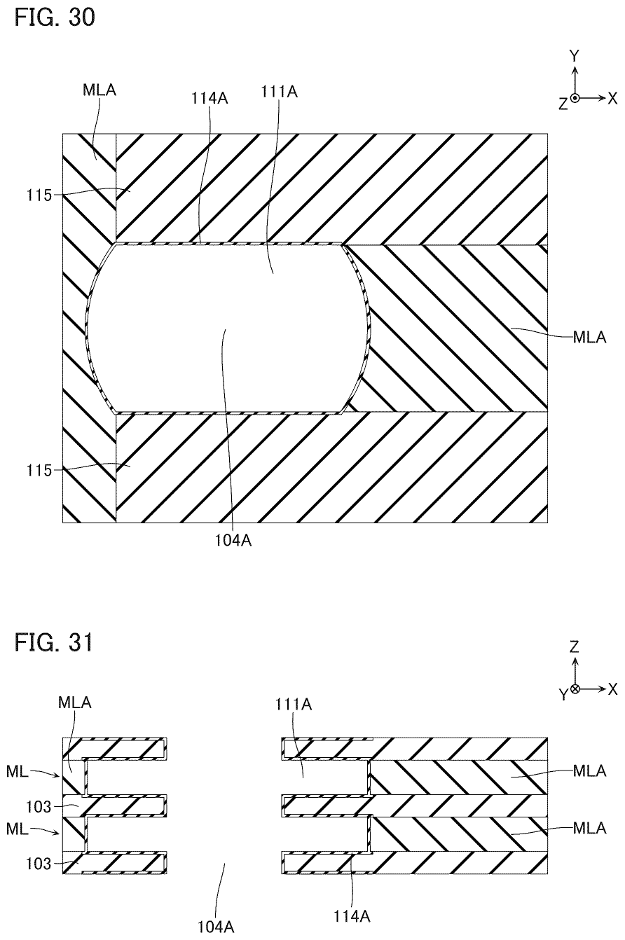

Next, as illustrated in FIGS. 30 and 31, for example, an insulating layer 114A is formed on an inner peripheral surface of the opening 104A, inner peripheral surfaces of the openings 111A, and an upper and lower surfaces of the insulating layers 103. The insulating layer 114A includes silicon oxide (SiO₂) containing boron (B), and the like. This process is performed by CVD, for example.

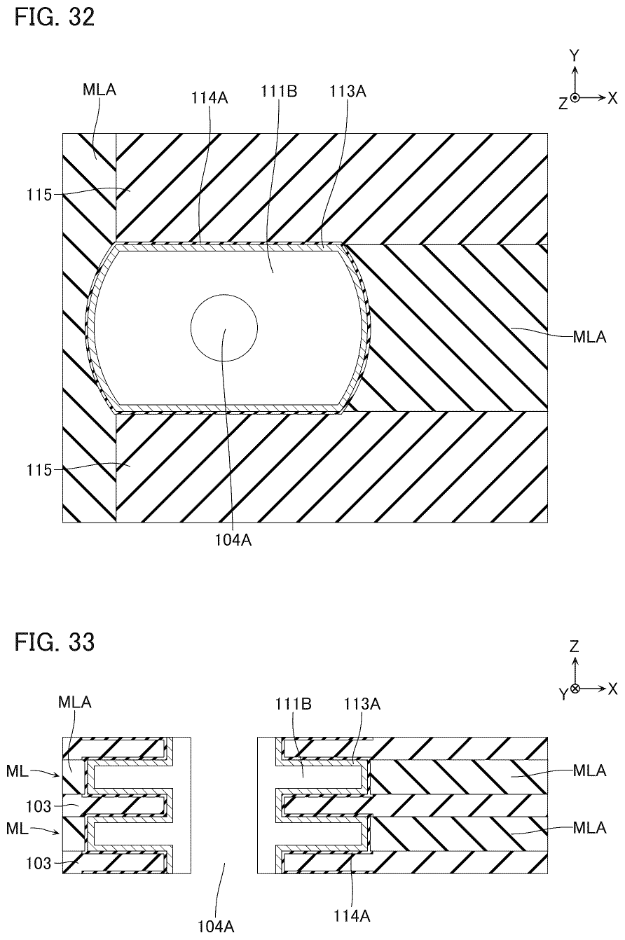

Next, as illustrated in FIGS. 32 and 33, for example, an conductive layer 113A and a sacrifice layer 111B, such as silicon (Si), are formed inside the openings 111A and the opening 104A. The conductive layer 113A is formed on upper surfaces and lower surfaces of the insulating layer 114A, exposed surfaces of the insulating layer 114A to the opening 104A, exposed surfaces of the insulating layer 114A to the openings 111A, and both side surfaces of the insulating layer 114A in the Y-direction. In addition, the openings 111A are filled with the sacrifice layer 111B, and the opening 104A is not filled with the sacrifice layer 111B. This process is performed by CVD, for example.

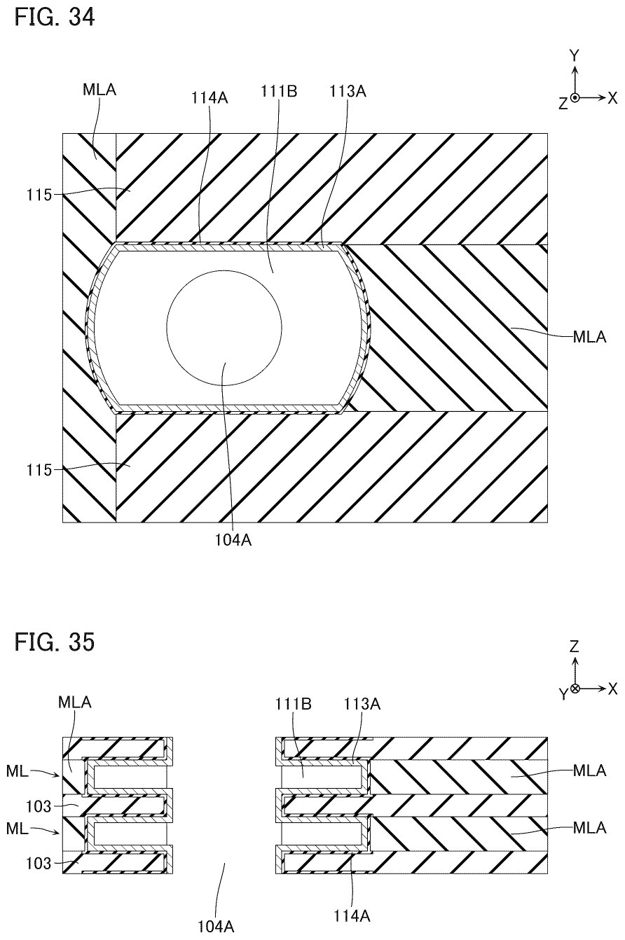

Next, for example, as illustrated in FIGS. 34 and 35, a part of the sacrifice layer 111B is removed to expose parts of the conductive layer 113A provided at the height positions corresponding to the insulating layers 103. This process is performed by wet etching, for example.

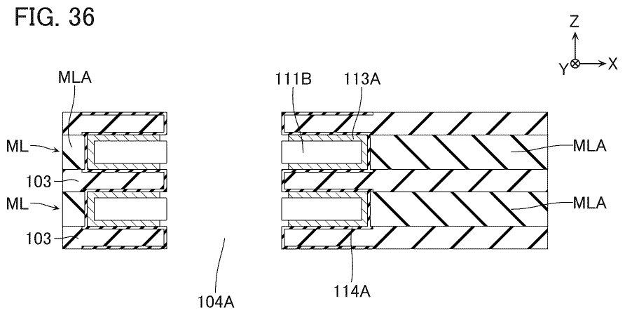

Next, for example, as illustrated in FIG. 36, the parts of the conductive layer 113A provided at the height positions corresponding to the insulating layers 103 are removed. This process is performed by wet etching, for example.

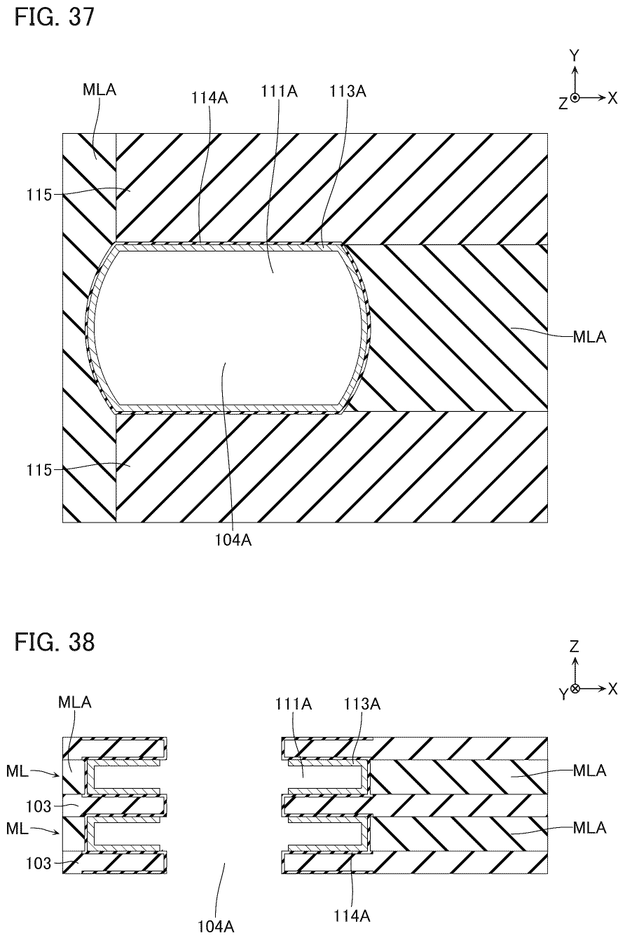

Next, for example, as illustrated in FIGS. 37 and 38, the sacrifice layer 111B is removed. This process is performed by wet etching, for example.

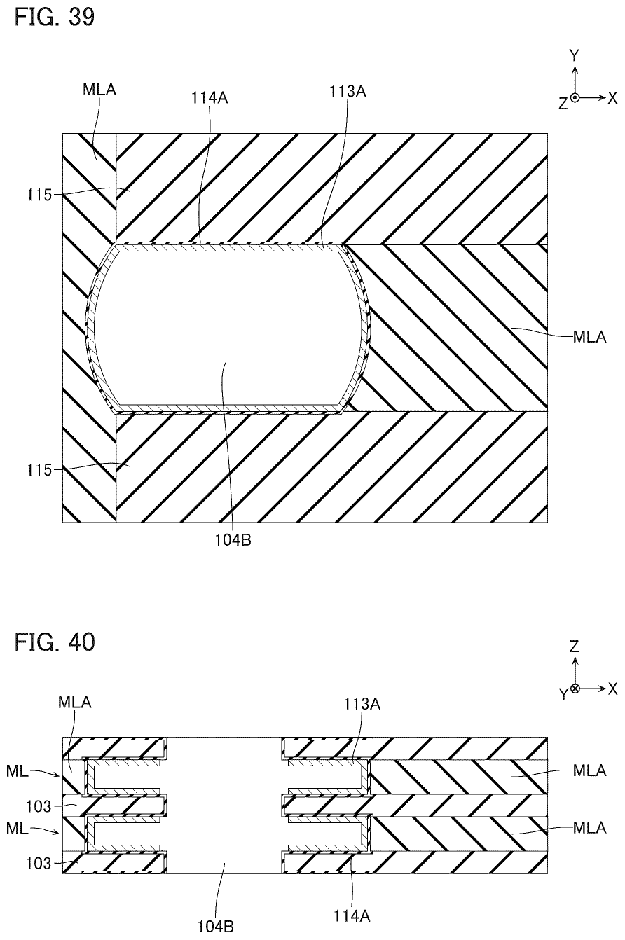

Next, as illustrated in FIGS. 39 and 40, for example, a sacrifice layer 104B, such as silicon (Si), is formed inside the opening 111A and the opening 104A. This process is performed by CVD, for example.

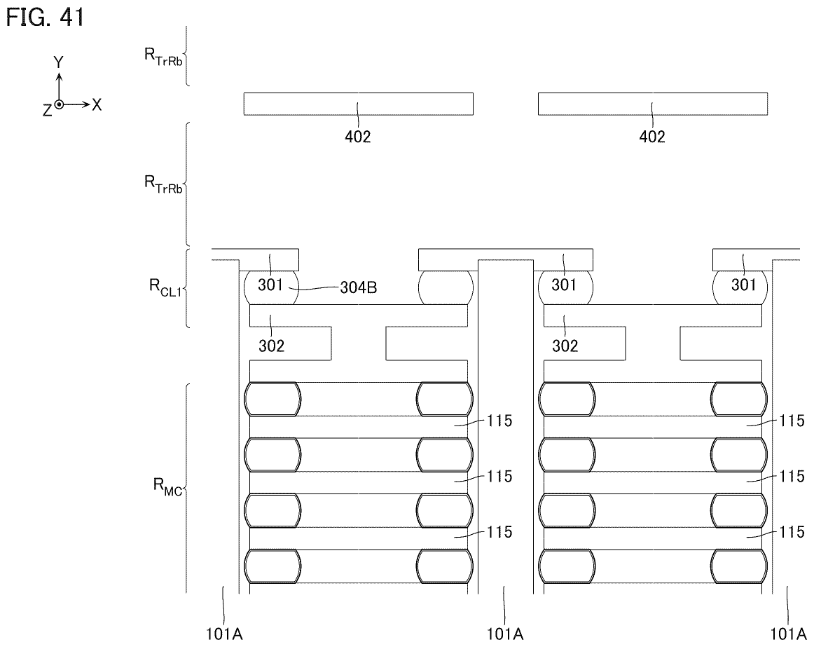

Next, as illustrated in FIG. 41, for example, openings 101A are formed at positions corresponding to the insulating layers 101. The opening 101A extends in the Y-direction and the Z-direction and penetrates the plurality of insulating layers 103 and the plurality of sacrifice layers MLA arranged in the Z-direction, and divides these configurations in the X-direction. This process is performed by RIE, for example.

Although it is omitted from the illustration, the conductive layer 501 (FIG. 5) is formed in the same way as the conductive layer 120. For example, in this process, an opening is formed also in the vicinity of the conductive layer 501 (FIG. 5). This opening extends in the X-direction and the Z-direction, penetrates the plurality of insulating layers 103 and the plurality of sacrifice layers MLA arranged in the Z-direction, and divides these configurations in the Y-direction. Similarly in the following processes, the process performed at a position corresponding to the conductive layer 120 is also performed at a position corresponding to the conductive layer 501.

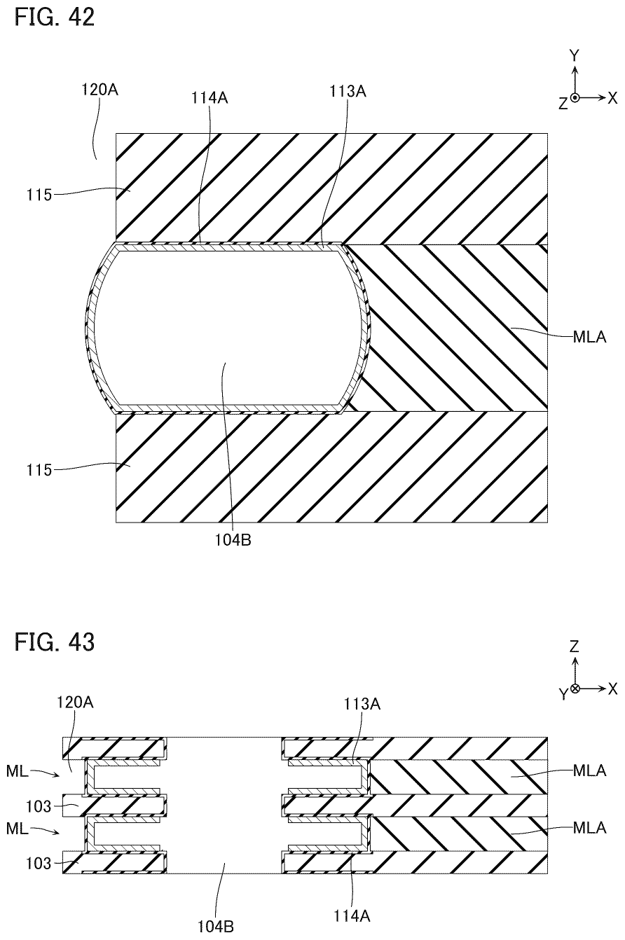

Next, for example, as illustrated in FIGS. 42 and 43, openings 120A are formed at positions corresponding to the conductive layers 120. Inside the opening 120A, a part of the upper surface of the insulating layer 103, a part of the lower surface of the insulating layer 103, a side surface of the insulating layer 114A in the X-direction, and side surfaces of the insulating layers 115 in the X-direction are exposed. In this process, for example, parts of the sacrifice layers MLA are removed through the opening 101A. This process is performed by wet etching, for example.

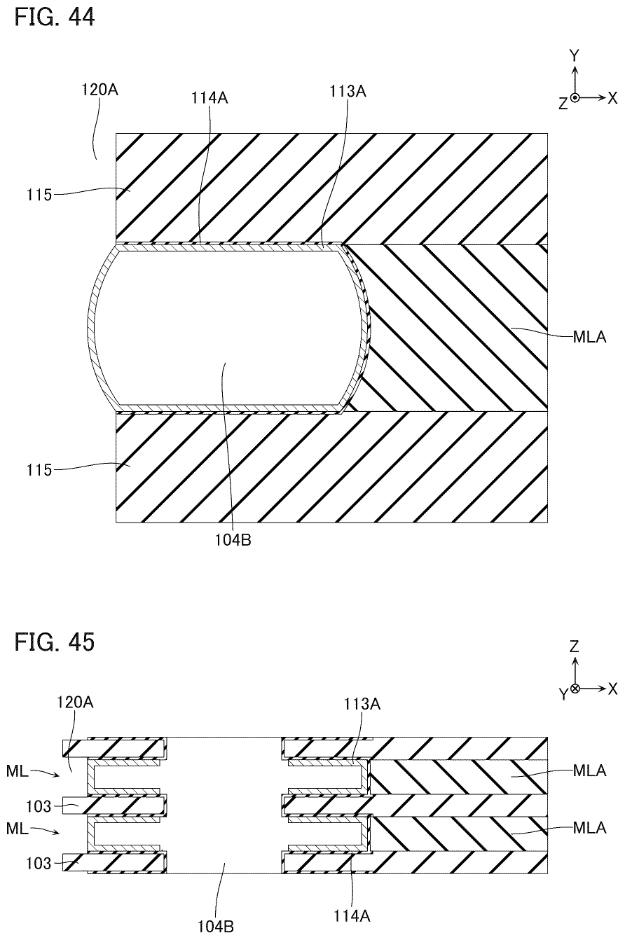

Next, for example, as illustrated in FIGS. 44 and 45, parts of the insulating layer 114A provided on exposed surfaces of the conductive layer 113A to the openings 120A, 101A in the X-direction are removed through the openings 120A, 101A. This process is performed by wet etching, for example.

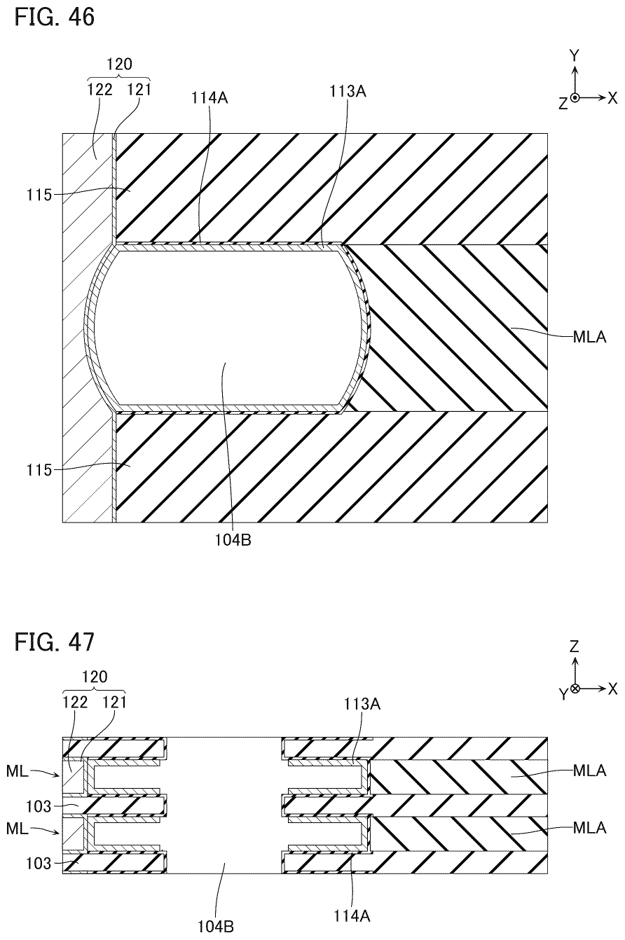

Next, for example, as illustrated in FIGS. 46 and 47, the conductive layers 120 are formed. In this process, for example, the barrier conductive films 121 and the conductive films 122 are formed inside the openings 120A, 101A by a method such as CVD. In this process, the openings 120A are filled with the barrier conductive films 121 and the conductive films 122 while the opening 101A is not filled. Next, for example by wet etching, a part of the barrier conductive films 121 and the conductive films 122 formed inside the opening 101A are removed. Although it is omitted from the illustration, after this process is performed, the insulating layer 101 is formed inside the opening 101A.

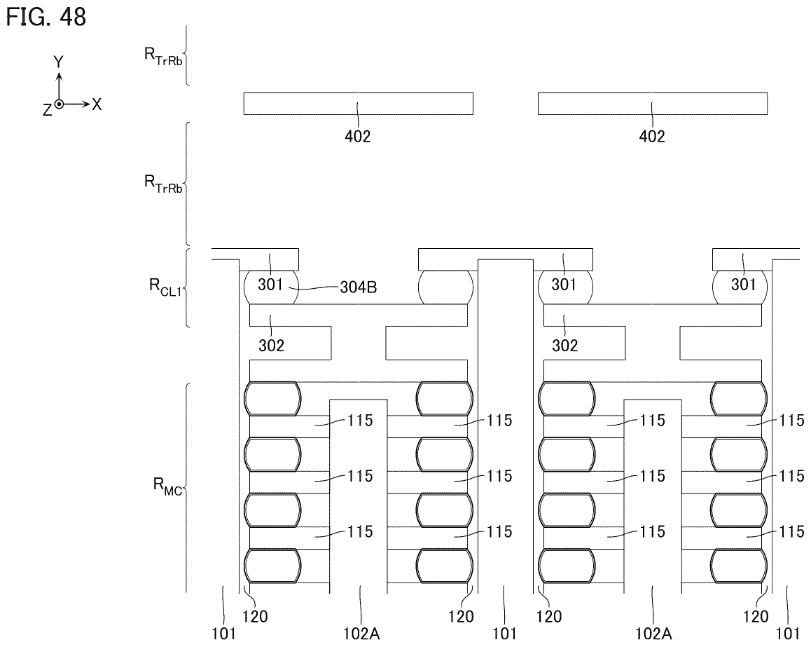

Next, for example, as illustrated in FIGS. 48 to 50, openings 102A are formed at positions corresponding to the conductive layers 102. The opening 102A extends in the Y-direction and the Z-direction, penetrates the plurality of insulating layers 103 and the plurality of sacrifice layers MLA arranged in the Z-direction, as well as the insulating layer 115, and divides these configurations in the X-direction. This process is performed by RIE, for example.

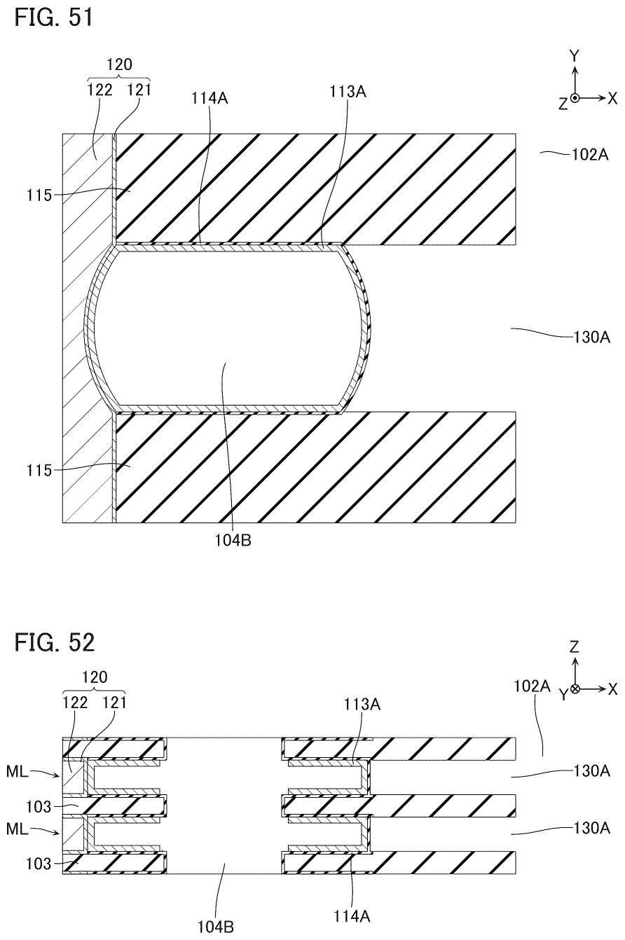

Next, as illustrated in FIGS. 51 and 52, for example, openings 130A are formed at positions corresponding to the capacitor structures 130. In this process, the sacrifice layers MLA are removed through the opening 102A. This process is performed by wet etching, for example.

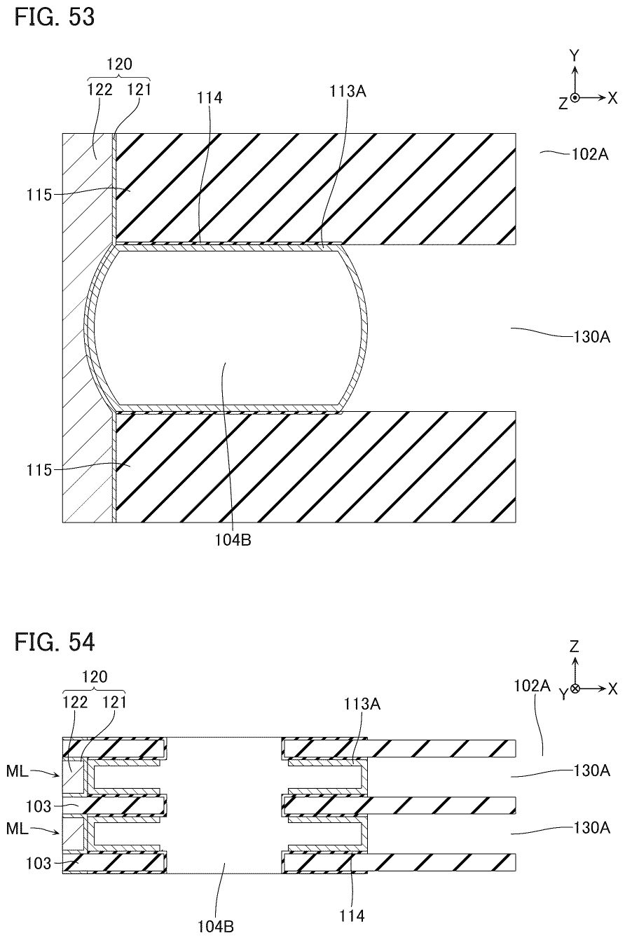

Next, as illustrated in FIGS. 53 and 54, for example, the insulating layers 114 are formed. In this process, for example, parts of the insulating layer 114A provided on side surfaces of the conductive layer 113A on the opening 102A side in the X-direction are removed through the openings 102A, 130A. This process is performed by wet etching, for example.

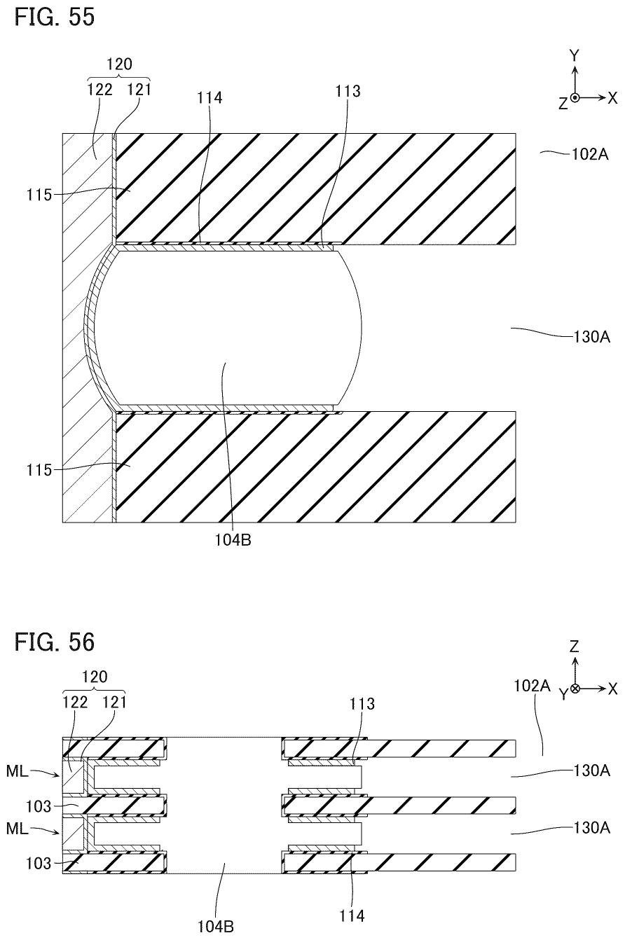

Next, for example, as illustrated in FIGS. 55 and 56, the conductive layers 113 are formed. In this process, for example, parts of the conductive layer 113A provided on side surfaces of the sacrifice layer 104B on the opening 102A side in the X-direction are removed through the openings 102A, 130A. This process is performed by wet etching, for example.

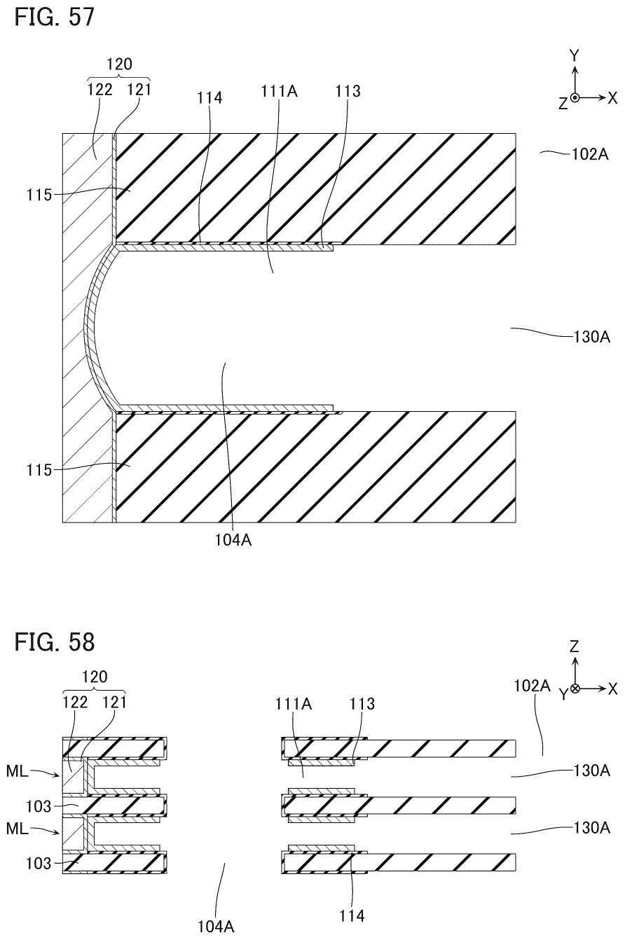

Next, for example, as illustrated in FIGS. 57 and 58, the sacrifice layer 104B is removed. This process is performed by wet etching, for example.

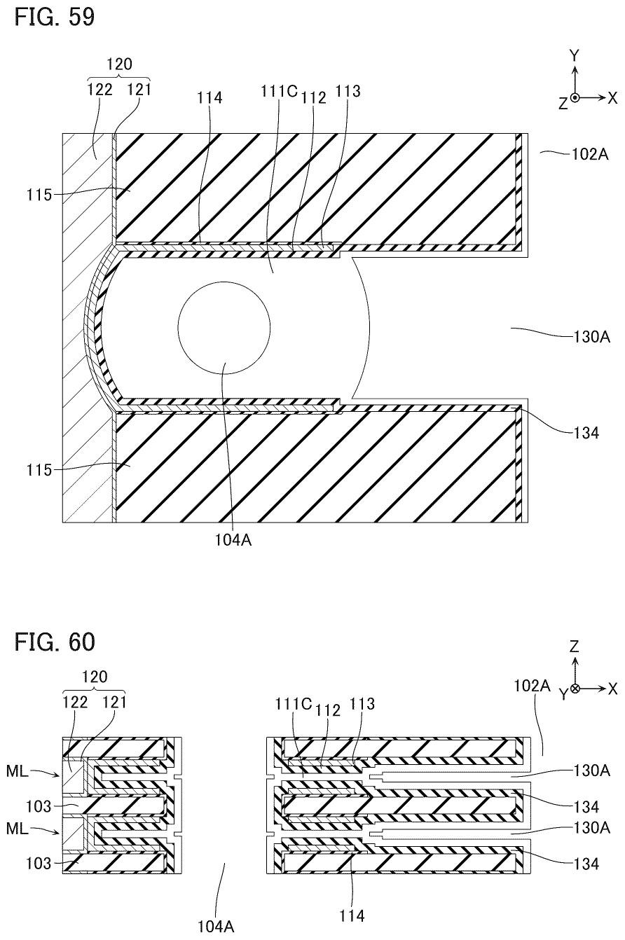

Next, as illustrated in FIGS. 59 and 60, for example, the insulating layers 112, 134 and a semiconductor layer 111C are formed inside the openings 111A, 104A, 130A, 102A. The insulating layers 112, 134 are formed on exposed surfaces of the conductive layers 113 to the opening 111A, parts of upper surfaces and parts of lower surfaces of the insulating layers 103, exposed surfaces of the insulating layers 103 to the opening 102A, exposed surfaces of the insulating layers 114 to the opening 104A, and parts of side surfaces of the insulating layers 115 in the Y-direction. In addition, the opening 111A is filled with the semiconductor layer 111C while the openings 104A, 130A, 102A are not filled with the semiconductor layer 111C. This process is performed by CVD, for example.

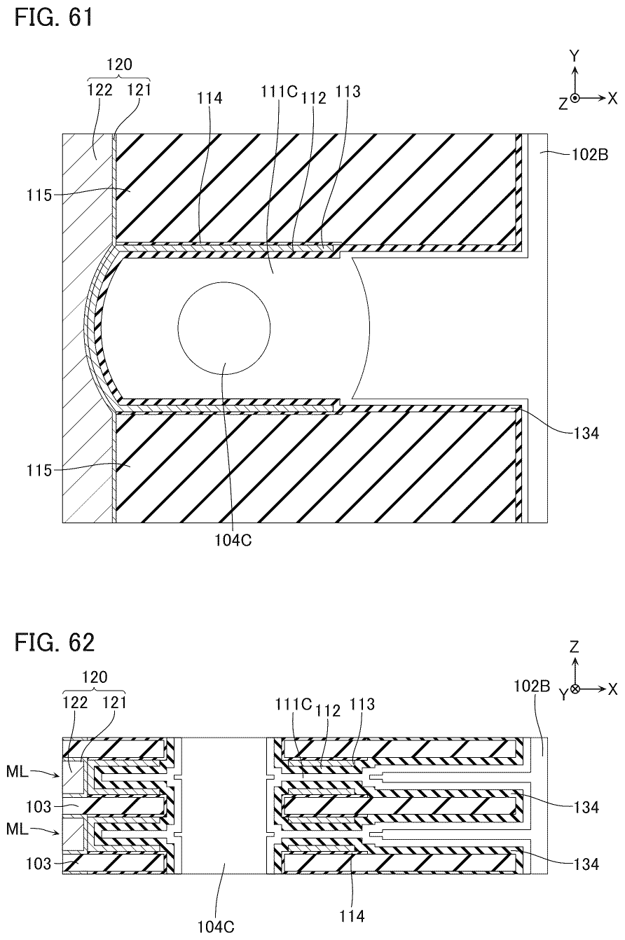

Next, as illustrated in FIGS. 61 and 62, for example, a sacrifice layer 104C, such as silicon (Si), is formed inside the opening 104A. In addition, a sacrifice layer 102B, such as silicon (Si), is formed inside the openings 102A, 130A. This process is performed by CVD, for example.

Next, as illustrated in FIGS. 63 and 64, for example, openings 204A are formed at positions corresponding to the via-wirings 204. The opening 204A extends in the Z-direction and penetrates the plurality of insulating layers 103 and the plurality of sacrifice layers MLA arranged in the Z-direction as illustrated in FIG. 64. This process is performed by RIE, for example.

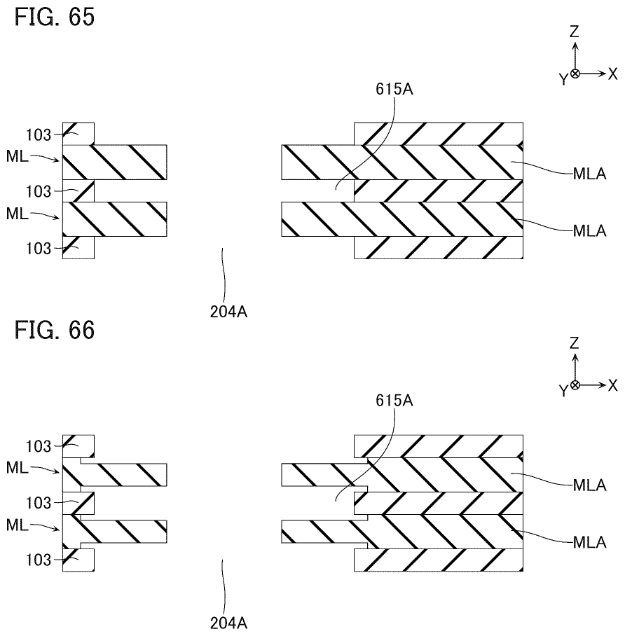

Next, as illustrated in FIG. 65, for example, openings 615A are formed at positions corresponding to the conductive layers 615. A part of an upper surface of the sacrifice layer MLA and a part of a lower surface of the sacrifice layer MLA are exposed inside the opening 615A. In this process, for example, parts of the insulating layers 103 are selectively removed through the opening 204A. This process is performed by wet etching, for example.

Although it is omitted from the illustration, the conductive layer 215, the insulating layer 214, and the semiconductor layer 213 (FIG. 12) are formed in the same way as the conductive layer 615, the insulating layer 614, and the semiconductor layer 613, respectively. For example, in this process, openings are also formed at positions corresponding to the conductive layers 215 (FIG. 12). In this process, for example, parts of the insulating layers 103 are selectively removed through the opening 204A. Similarly in the following processes, the process performed at positions corresponding to the conductive layer 615, the insulating layer 614, and the semiconductor layer 613 are also performed at positions corresponding to the conductive layer 215, the insulating layer 214, and the semiconductor layer 213.

Next, for example, as illustrated in FIG. 66, parts of the sacrifice layers MLA are removed. In this process, widths of the openings 615A in the Z-direction are increased. This process is performed by wet etching, for example.

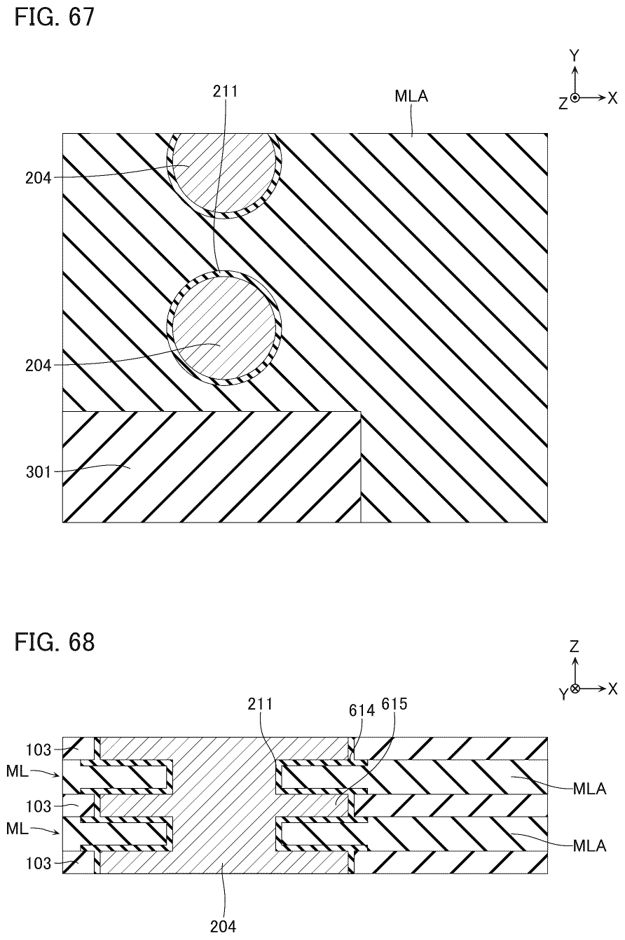

Next, as illustrated in FIGS. 67 and 68, for example, the insulating layers 211, 614, the conductive layers 615, and the via-wiring 204 are formed inside the openings 615A, 204A. This process is performed by CVD, for example.

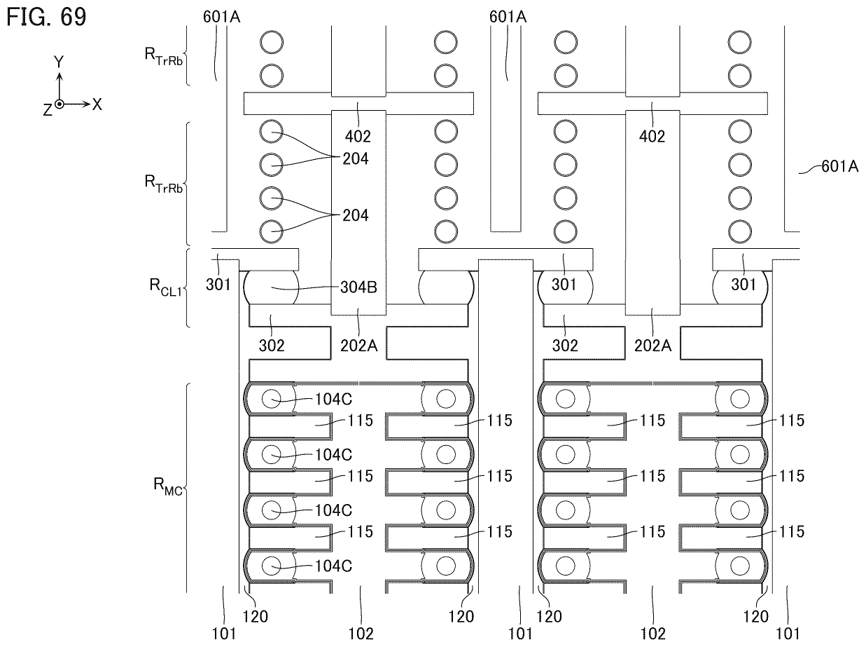

In addition, as illustrated in FIGS. 69 to 73, for example, openings 601A, 202A are formed at positions corresponding to the conductive layers 601 and the insulating layers 202, respectively. In addition, although it is omitted from the illustration, openings similar to the openings 601A are formed at positions corresponding to the insulating layers 201 (FIG. 5). The openings 601A, 202A and the openings corresponding to the insulating layers 201 (FIG. 5) extend in the Y-direction and the Z-direction, penetrate the plurality of insulating layers 103 and the plurality of sacrifice layers MLA arranged in the Z-direction, and divide these configurations in the X-direction. This process is performed by RIE, for example.

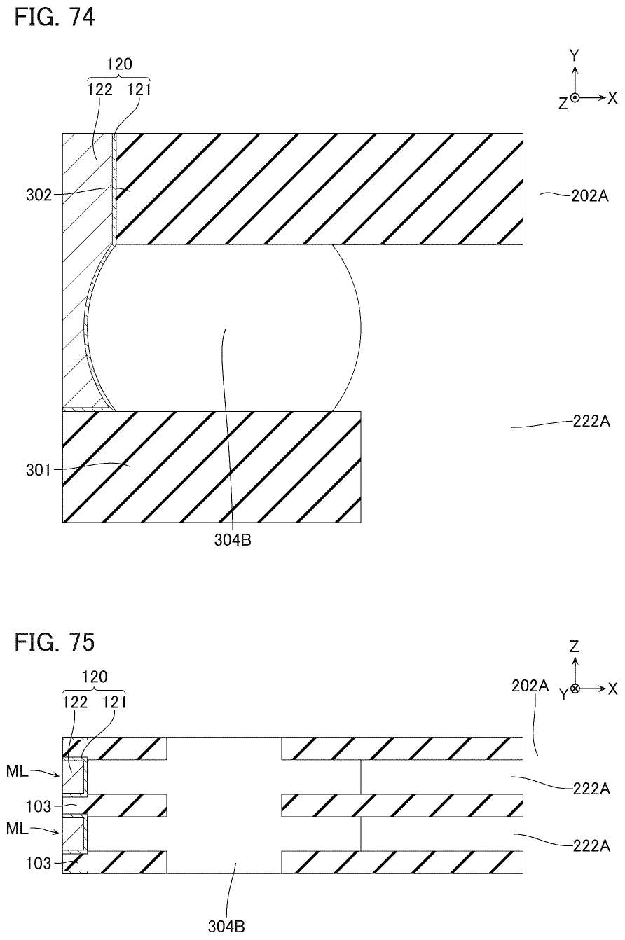

Next, as illustrated in FIGS. 74 to 77, for example, openings 222A, 621A, 622A, 613A are formed at positions corresponding to the conductive layers 222, 621, 622, and the semiconductor layers 613. Parts of upper surfaces and parts of lower surfaces of the insulating layers 103, and parts of side surfaces of the insulating layers 302, 402 on one side in the Y-direction are exposed to insides of the openings 222A, 622A. A part of an upper surface of the insulating layer 103, a part of a lower surface of the insulating layer 103, and a part of a side surface of the insulating layer 301 on one side in the Y-direction are exposed to inside of the opening 621A. An upper surface and a lower surface of the insulating layer 614, outer peripheral surfaces of the insulating layers 211, and parts of side surfaces of the insulating layers 301, 402 on one side in the Y-direction are exposed to inside of the opening 613A. In this process, for example, parts of the sacrifice layers MLA are selectively removed through the openings 222A, 621A, 622A. This process is performed by wet etching, for example.

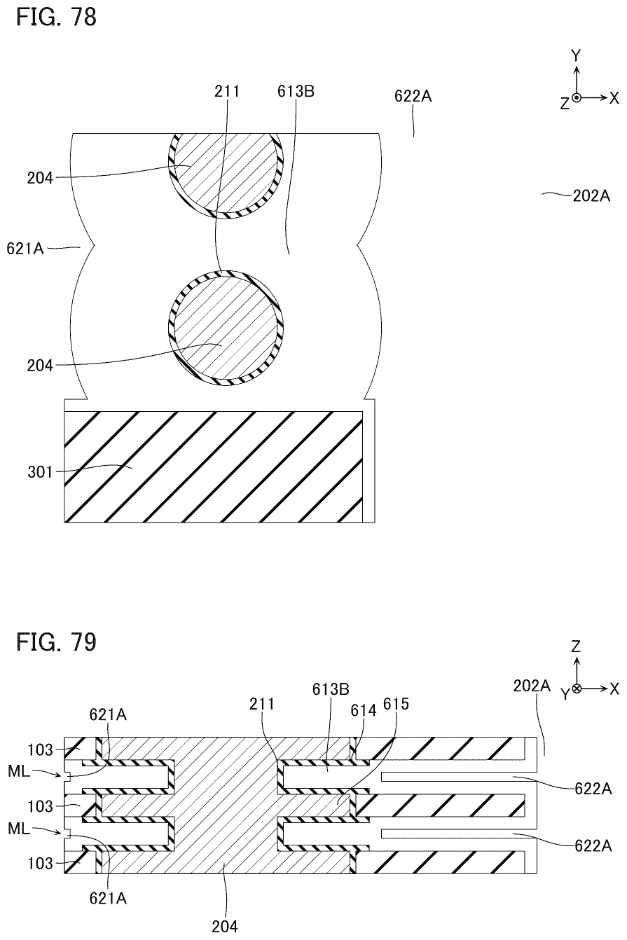

Next, as illustrated in FIGS. 78 and 79, for example, a semiconductor layer 613B is formed inside the openings 613A, 622A, 202A, 621A, 601A. The openings 613A are filled with the semiconductor layer 613B while the openings 622A, 202A, 621A, 601A are not filled with the semiconductor layer 613B. This process is performed by CVD, for example.

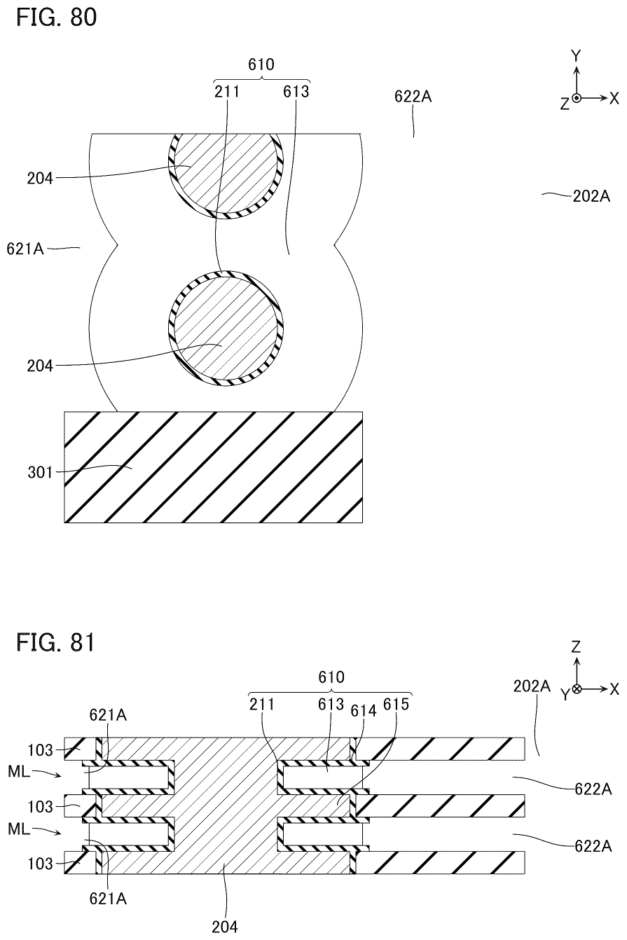

Next, as illustrated in FIGS. 80 and 81, for example, the semiconductor layers 613 are formed. In this process, for example, parts of the semiconductor layer 613B are removed by a method such as wet etching. Specifically, parts of the semiconductor layer 613B formed inside the openings 613A are left, and the other parts are removed.

Next, an upper part of the opening 601A is closed using an insulating layer, or the like, which is not illustrated.

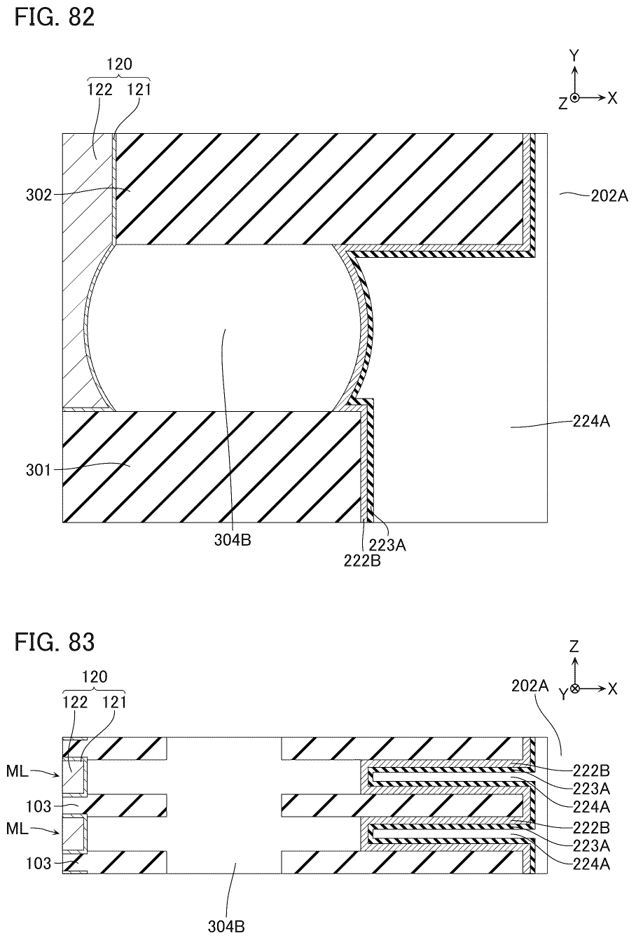

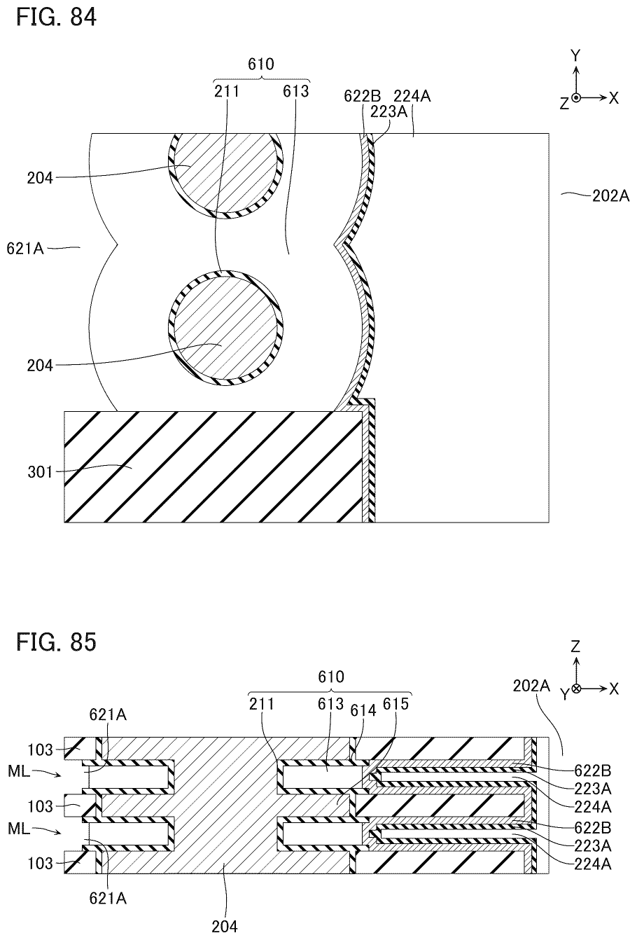

Next, as illustrated in FIGS. 82 and 83, for example, a conductive layer 222B, an insulating layer 223A, and a sacrifice layer 224A are formed inside the openings 222A, 202A. Also, as illustrated in FIGS. 84 and 85, for example, a conductive layer 622B, the insulating layer 223A, and the sacrifice layer 224A are formed inside the openings 622A, 202A. The conductive layers 222B, 622B are formed on parts of upper surfaces and parts of lower surfaces of the insulating layers 103, exposed surfaces of the insulating layers 103 to the opening 202A, parts of upper surfaces and parts of lower surfaces of the insulating layers 214, 614, outer peripheral surfaces of the semiconductor layers 213, 613, a side surface of the insulating layer 301 on one side in the X-direction, and side surfaces of the insulating layers 302, 402 on one side in the Y-direction. The openings 222A, 622A are filled with the insulating layer 223A and the sacrifice layer 224A while the opening 202A is not filled with the insulating layer 223A and the sacrifice layer 224A. This process is performed by ALD, CVD, or the like, for example.

In this process, a conductive layer corresponding to the conductive layer 221, an insulating layer 223A, and a sacrifice layer 224A are formed inside openings corresponding to the conductive layers 221 (FIGS. 11 and 12) and the insulating layer 201 (FIG. 5) which are not illustrated. The conductive layer corresponding to the conductive layer 221 is formed on parts of upper surfaces and parts of lower surfaces of the insulating layers 103, exposed surfaces of the insulating layers 103 to the opening corresponding to the insulating layer 201 which is not illustrated, parts of upper surfaces and parts of lower surfaces of the insulating layers 214, outer peripheral surfaces of the semiconductor layer 213, a side surface of the insulating layer 402 on one side in the X-direction, and side surfaces of the insulating layers 301, 401 on one side in the Y-direction. The openings corresponding to the conductive layers 221 are filled with the insulating layer 223A and the sacrifice layer 224A while the opening corresponding to the insulating layer 201 which is not illustrated is not filled with the insulating layer 223A and the sacrifice layer 224A.

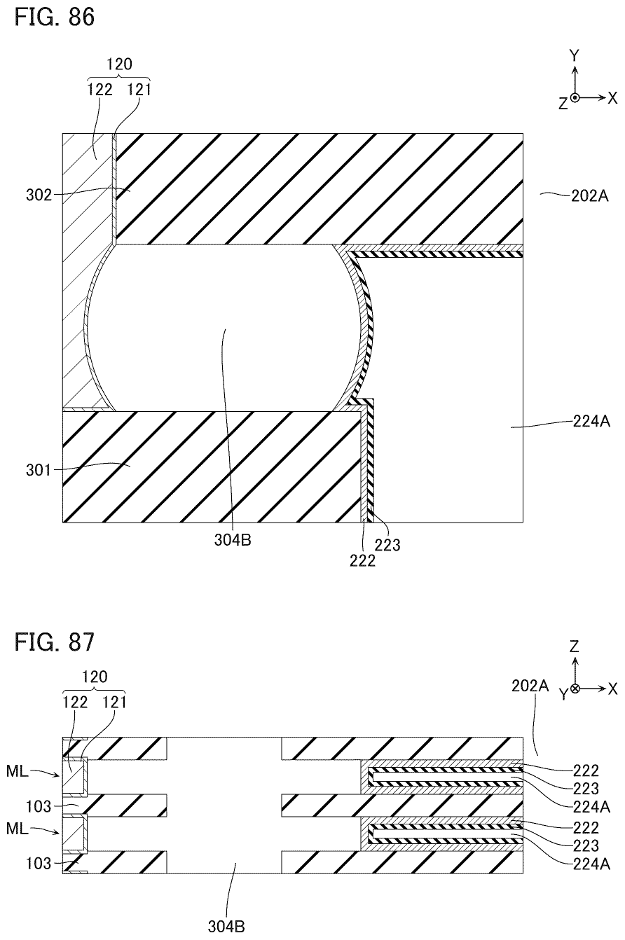

Next, as illustrated in FIGS. 86 to 89, the conductive layers 222, 622 and the insulating layers 223 are formed. Also, the conductive layers 221 (FIGS. 11 and 12) are formed. In this process, among the conductive layers 222B, 622B, the conductive layer corresponding to the conductive layer 221 which is not illustrated, the insulating layer 223A, and the sacrifice layer 224A, parts formed on exposed surfaces of the insulating layers 103 to the opening 202A and the opening corresponding to the insulating layer 201 (FIG. 5) which is not illustrated are removed and the insulating layers 103 are exposed to the opening 202A. This process divides the conductive layers 222B, 622B, the conductive layer corresponding to the conductive layers 221 which is not illustrated, and the insulating layer 223A in the Z-direction to form the conductive layers 222, 622, 221, and the insulating layers 223. This process is performed by wet etching, for example.

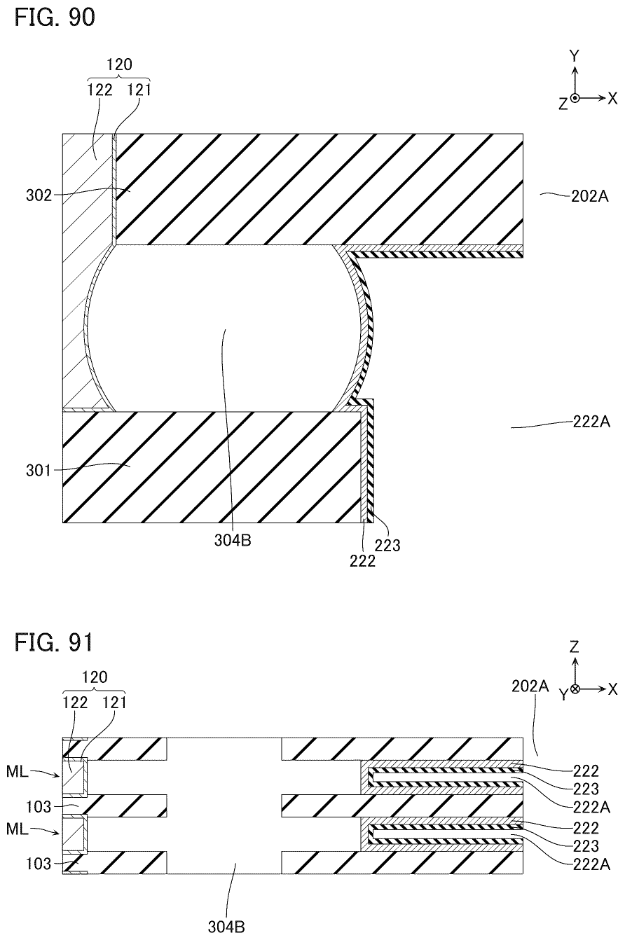

Next, as illustrated in FIGS. 90 to 93, the sacrifice layer 224A is removed. This process is performed by wet etching, for example.

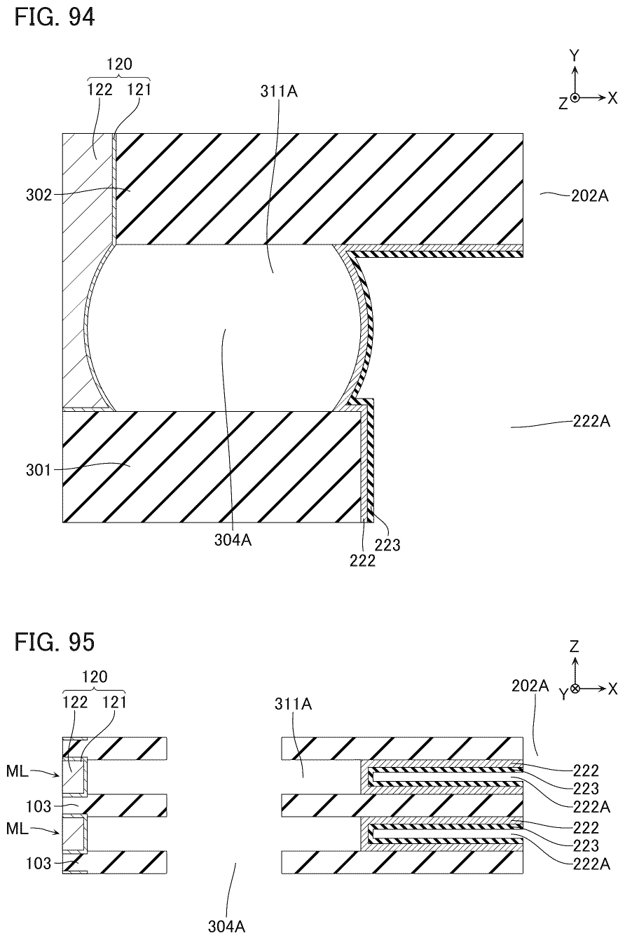

Next, as illustrated in FIGS. 94 and 95, the sacrifice layer 304B is removed. This process is performed by wet etching, for example.

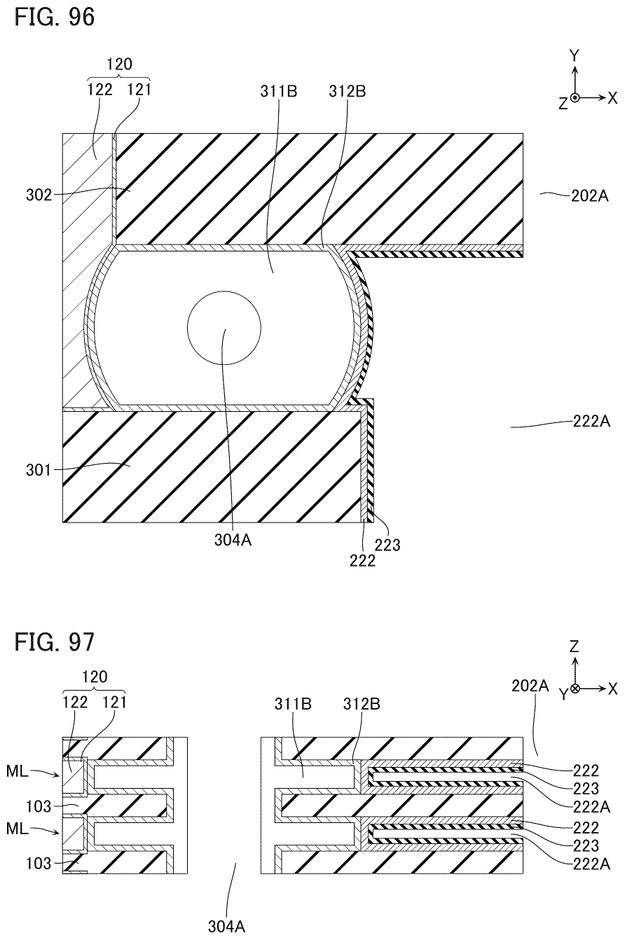

Next, as illustrated in FIGS. 96 and 97, for example, a conductive layer 312B and a semiconductor layer 311B are formed inside openings 311A, 304A. The conductive layer 312B is formed on parts of upper surfaces and parts of lower surfaces of the insulating layers 103, exposed surface of the insulating layers 103 to the opening 304A, side surfaces of the conductive layers 222 on one side in the X-direction, and side surfaces of the conductive layers 120 on one side in the X-direction. The openings 311A are filled with the semiconductor layer 311B while the opening 304A is not filled with the semiconductor layer 311B. This process is performed by CVD, for example.

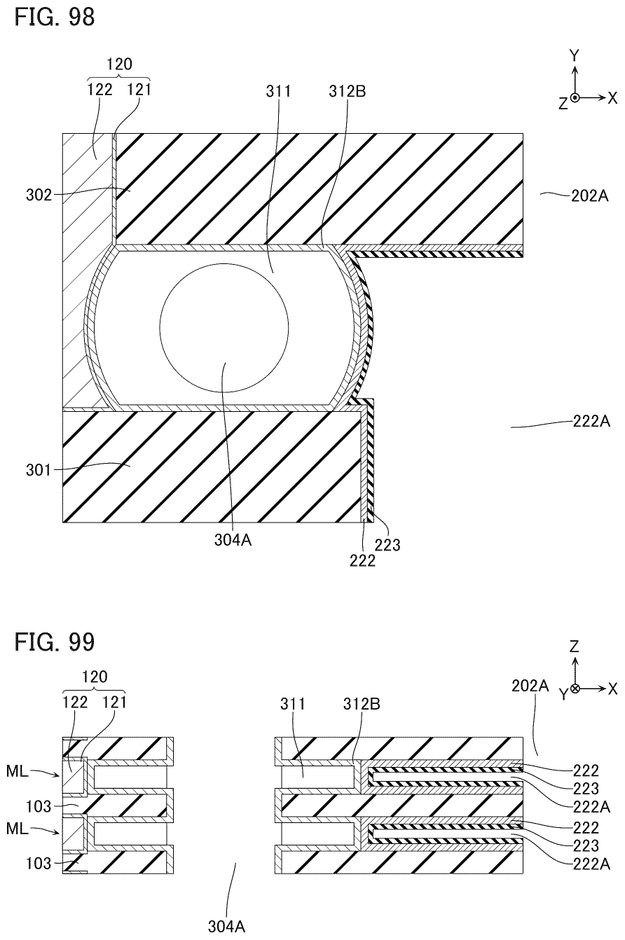

Next, as illustrated in FIGS. 98 and 99, the semiconductor layers 311 are formed. In this process, parts of the semiconductor layer 311B formed on inner peripheral surfaces of the opening 304A of the insulating layers 103 are removed and parts of the conductive layer 312B are exposed to the opening 304A. This process divides the semiconductor layer 311B in the Z-direction to form the plurality of semiconductor layers 311 arranged in the Z-direction. This process is performed by wet etching, for example.

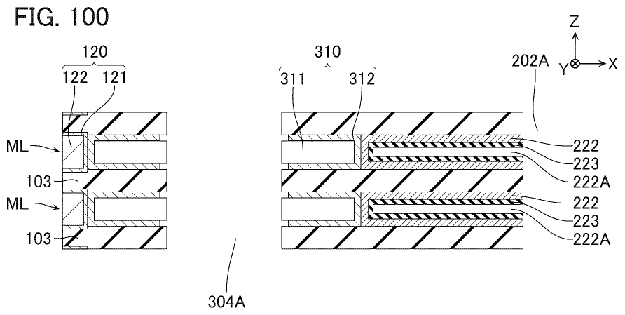

Next, as illustrated in FIG. 100, the conductive layers 312 are formed. In this process, the parts of the conductive layer 312B formed on the inner peripheral surfaces of the opening 304A of the insulating layers 103 are removed to expose the insulating layer 103 to the opening 304A. This divides the conductive layer 312B in the Z-direction to form the plurality of conductive layers 312 arranged in the Z-direction. This process is performed by wet etching, for example.

Next, as illustrated in FIGS. 9 to 12, FIG. 101, and FIG. 102, the insulating layer 224 is formed inside the openings 222A, 622A, and an opening, corresponding to the conductive layer 221 which is not illustrated, and the insulating layer 202 is formed inside the opening 202A. The insulating layer 304 is also formed inside the opening 304A. This process is performed by CVD, for example.

Next, as illustrated in FIG. 15, the conductive layers 621, 602, 601 are formed inside the openings 621A, 601A. This process is performed by ALD and CVD, for example.

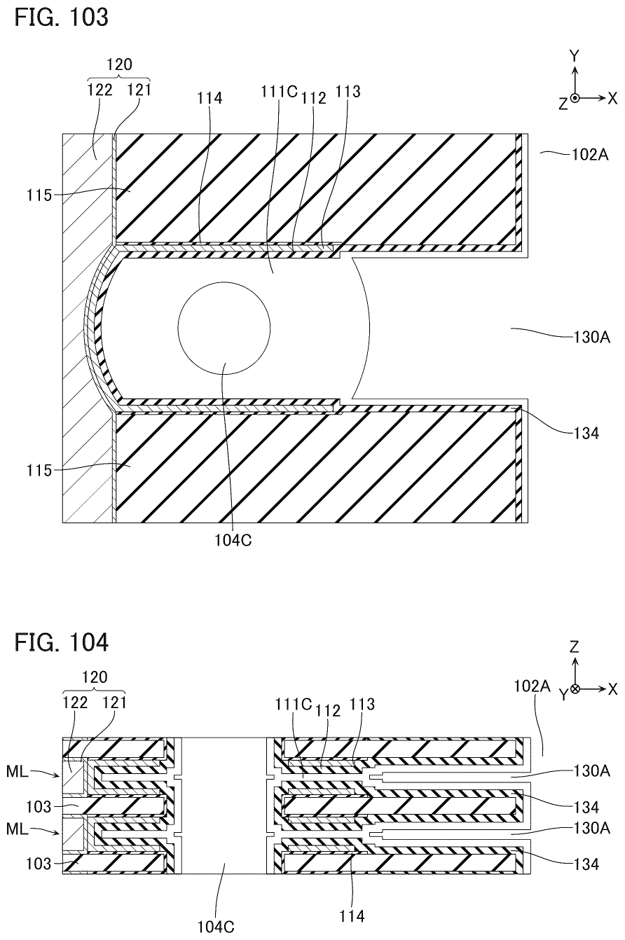

Next, for example, as illustrated in FIGS. 103 and 104, the sacrifice layer 102B is removed. This process is performed by wet etching, for example.

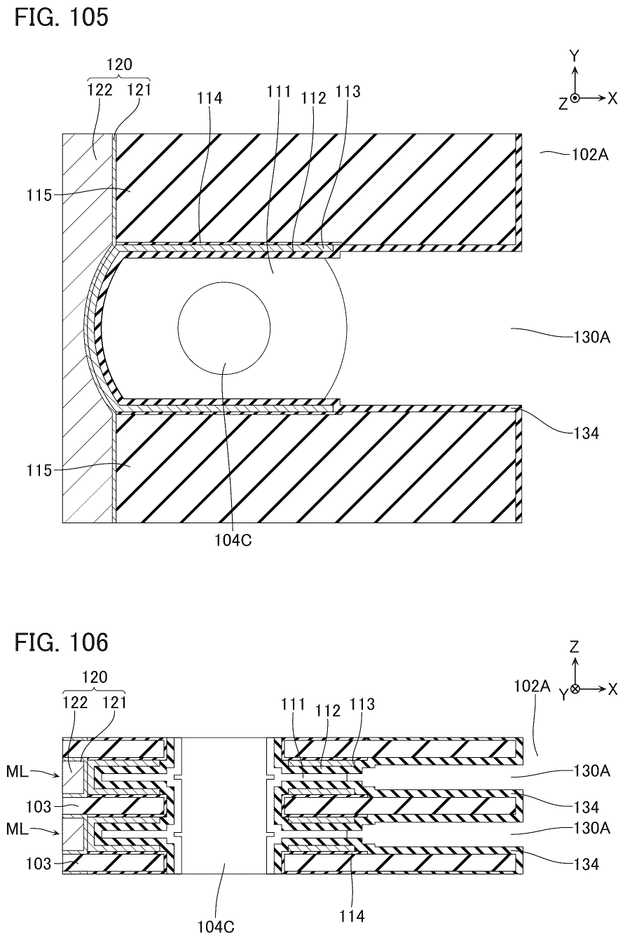

Next, the semiconductor layers 111 are formed as illustrated in FIGS. 105 and 106. In this process, parts of the semiconductor layer 111C formed on exposed surfaces of the insulating layer 134 to the openings 130A, 102A are removed to divide the semiconductor layer 111C in the Y-direction and the Z-direction. This process is performed by wet etching, for example.

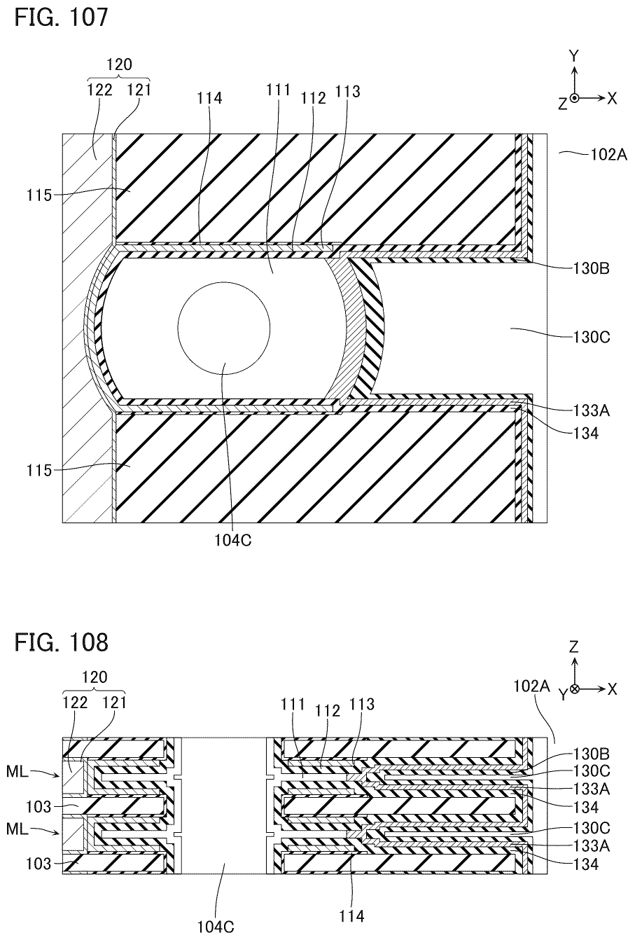

Next, as illustrated in FIGS. 107 and 108, for example, a conductive layer 133A, an insulating layer 130B, and a sacrifice layer 130C are formed on side surfaces of the semiconductor layers 111 on one side (on the opening 102A side) in the X-direction, and exposed surfaces of the insulating layer 134 to the openings 130A, 102A. This process is performed by ALD, CVD, for example.

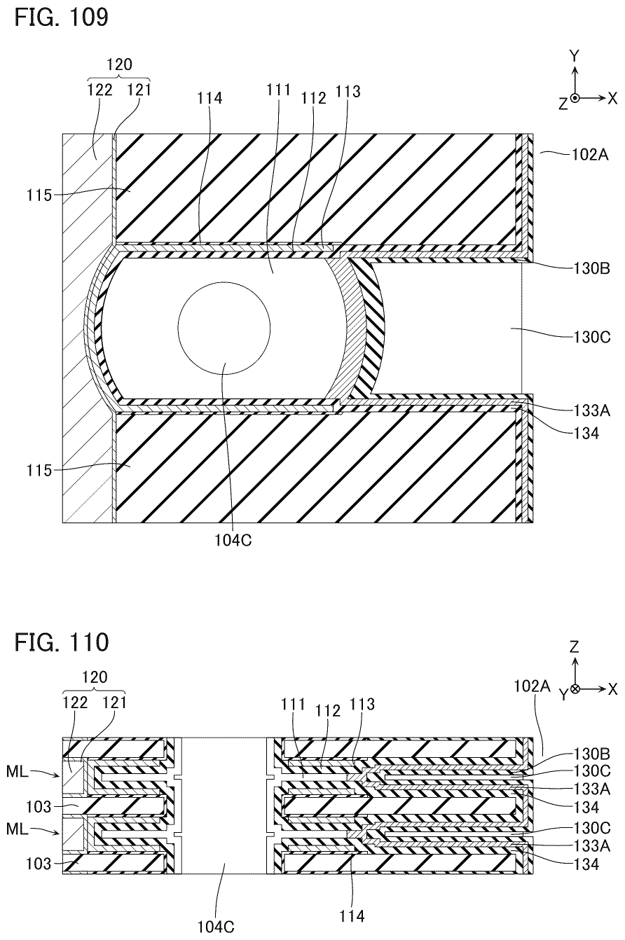

Next, for example, as illustrated in FIGS. 109 and 110, a part of the sacrifice layer 130C is removed through the opening 102A. In this process, for example, a part of the insulating layer 130B corresponding to side surfaces of the insulating layers 115 and the insulating layers 103 in the X-direction are exposed. This process is performed by wet etching, for example.

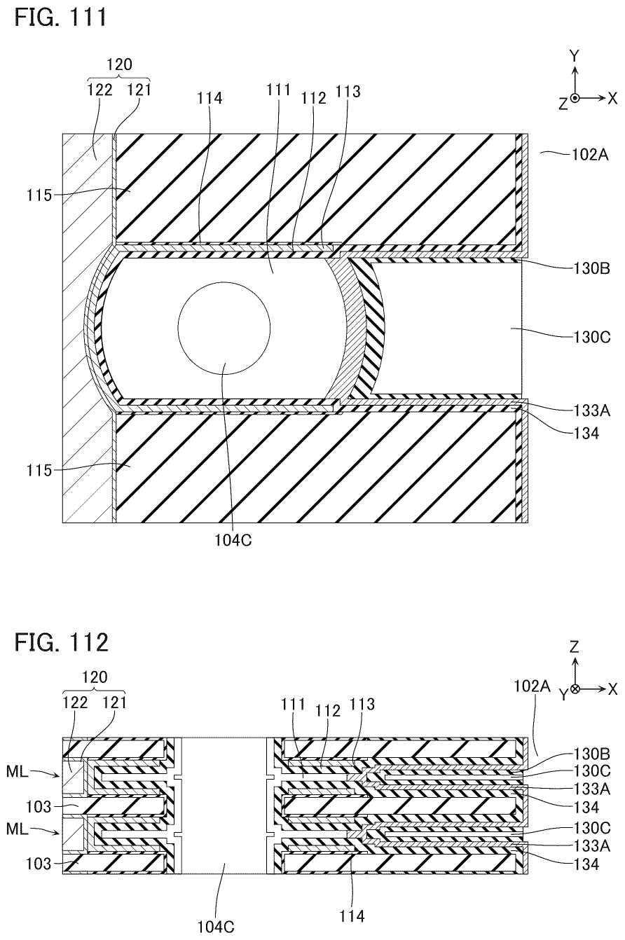

Next, for example, as illustrated in FIGS. 111 and 112, parts of the insulating layer 130B are removed through the opening 102A. In this process, for example, parts of the conductive layer 133A corresponding to side surfaces of the insulating layers 115 and the insulating layers 103 in the X-direction are exposed. This process is performed by wet etching, for example.

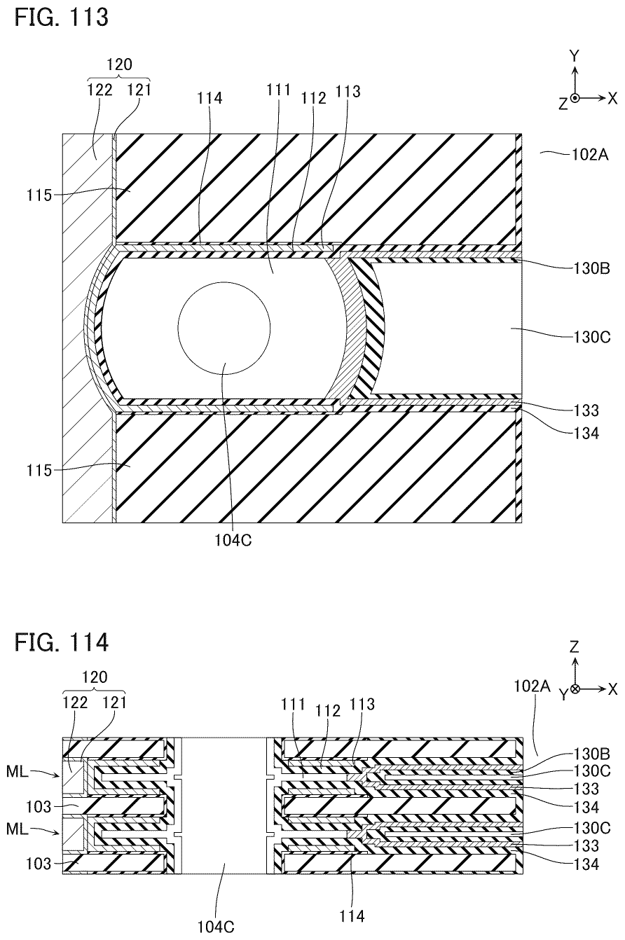

Next, for example, as illustrated in FIGS. 113 and 114, the conductive layers 133 are formed. In this process, for example, parts of the conductive layer 133A provided on side surfaces of the insulating layers 115 and the insulating layers 103 in the X-direction are removed, and the conductive layer 133A is divided in the Y-direction and the Z-direction. This process is performed by wet etching, for example.

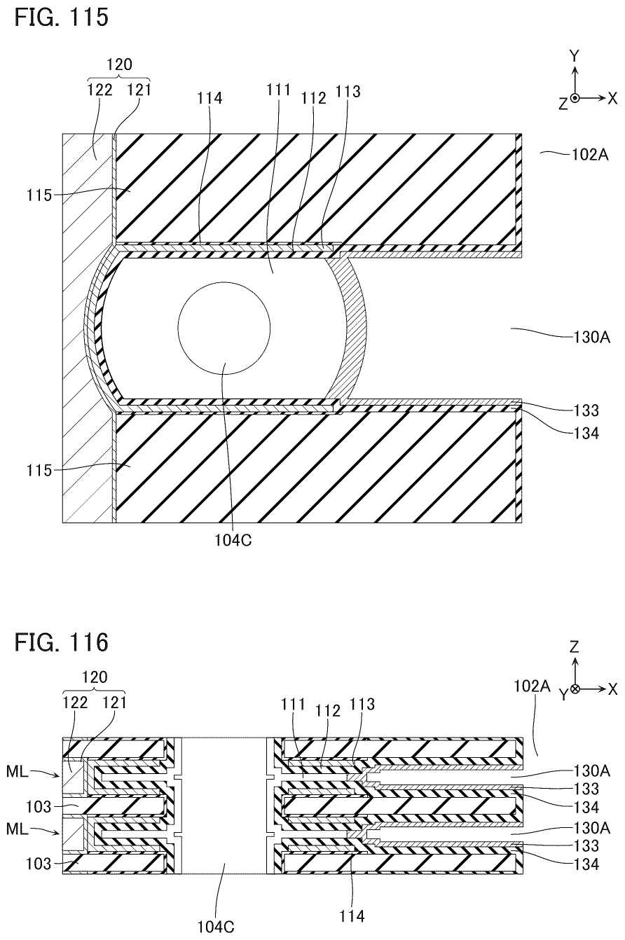

Next, for example, as illustrated in FIGS. 115 and 116, the sacrifice layer 130C and the insulating layer 130B are removed through the opening 102A. This process is performed by wet etching, for example.

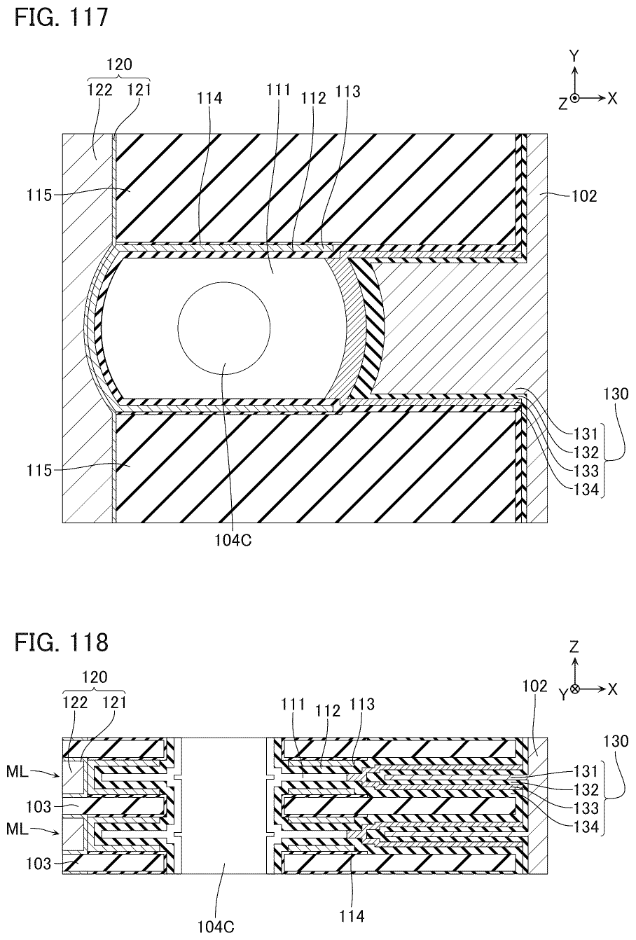

Next, for example, as illustrated in FIGS. 117 and 118, the capacitor structures 130 and the conductive layer 102 are formed. In this process, for example, the insulating layers 132 and the conductive layers 131, 102 are formed on upper surfaces, lower surfaces, side surfaces on one side (on the opening 102A side) in the X-direction, and side surfaces on both sides in the Y-direction of the conductive layers 133, and side surfaces of the insulating layer 134 in the X-direction. This process is performed by CVD, for example.

Subsequently, the semiconductor memory device according to the first embodiment is manufactured by removing the sacrifice layer 104C and forming the via-wiring 104 (FIGS. 7 and 8).

### Effect

As described with reference to FIG. 1, in the semiconductor memory device according to the first embodiment, gate voltages of the transistors TrRa, TrRb are common between the plurality of memory layers ML. With this type of configuration, as described with reference to FIG. 12, it is possible to provide the conductive layer 215 that functions as the gate electrodes of the transistors TrRa, TrRb at the height position corresponding to the insulating layer 103, and to serve as the common gate electrode of the two transistors TrRa, TrRb adjacent to one another in the Z-direction. This makes it possible to increase thicknesses of gate insulating films of the transistors TrRa, TrRb without hindering the high integration of the semiconductor memory device. Therefore, it is possible to set the voltage V_{ON}′ described with reference to FIG. 2 to a voltage that is sufficiently larger than the voltage V_{ON}, and to increase a speed of transferring the voltage V_{ON} to the selected word line WL in the read operation.

In order to connect the plurality of layer select lines LL to the peripheral circuit, for example, it is possible to provide terrace portions on the plurality of conductive layers 501 (FIG. 5) and connect via contact electrodes to these terrace portions. A terrace portion is, for example, a part of an upper surface of the conductive layer 501 that does not overlap with any other conductive layers when viewed from above. The memory cell array (MCA) requires the number of terrace portions that is the same as the number of the memory layers (ML) arranged in the Z-direction.

As described here with reference to FIG. 2, the two transistors TrRa, TrRb are connected to the word line WL. In order to achieve such a configuration, for example, it is possible to provide the transistor region R_{TrRa} and the wiring region R_{LL}, which are described with reference to FIG. 5, and the like on each of one side and the other side in the Y-direction with respect to the memory cell region RMC (FIGS. 5 and 6). However, when this type of configuration is adopted, it may be necessary to provide the same number of terrace portions on the one side and the other side in the Y-direction with respect to the memory cell region R_{MC} (FIGS. 5 and 6) as the number of memory layers ML arranged in the Z-direction, which may hinder the reduction in the circuit area.

In this embodiment, the plurality of conductive layers 621 arranged in the Z-direction in a region on the other side of the memory cell region R_{MC} in the Y-direction are connected in common to the conductive layers 601, 602 extending in the Z-direction, and the wiring region R_{LL} is omitted. With this type of configuration, it is possible to reduce the circuit area of the memory cell array MCA by omitting the terrace portion in the region on the other side of the memory cell region R_{MC} in the Y-direction.

In addition, when the plurality of conductive layers 621 arranged in the Z-direction are connected in common to a conductive layer extending in the Z-direction, it is also possible to provide the conductive layer extending in the Z-direction at a position corresponding to the wiring region R_{LL} on the other side of the memory cell region R_{MC} in the Y-direction. However, in this embodiment, the conductive layers 601, 602 are provided at positions arranged with the semiconductor layer 613, the insulating layer 614, and the conductive layer 615 in the X-direction. With this type of configuration, it is not necessary to provide a region for the conductive layers 601, 602, and thus, it is possible to further reduce the circuit area of the memory cell array MCA.

In the transistor structure 110 according to the embodiment, the conductive layer 113 is opposed to an upper surface and a lower surface of the semiconductor layer 111, and both side surfaces of the semiconductor layer 111 in the Y-direction.

With this configuration, it is possible to reduce the interference of electric fields between the plurality of semiconductor layers 111 arranged in the Z-direction. Therefore, even when the high integration of the memory cell array MCA in the Z-direction is achieved, it is possible to control the semiconductor layers 111 to appropriately enter the ON state or the OFF state, and it is possible to provide the semiconductor memory device configured to operate appropriately.

When the transistor TrC is set to the ON state, channels are formed on an upper surface and a lower surface of the semiconductor layer 111, and on both side surfaces of the semiconductor layer 111 in the Y-direction. Therefore, it is possible to make the ON current of the transistor TrC relatively large. This makes it possible to achieve faster and more stable operation.

In this embodiment, the conductive layer 120, which functions as the word line WL, is provided on the opposite side of the plate line PL with respect to the transistor structure 110, and is provided at a position that does not overlap with the transistor structure 110 when viewed from the Z-direction. Therefore, it is possible to form the conductive layer 120 and the transistor structure 110 independently, and it is possible to manufacture them relatively easily. In addition, it is possible to reduce the width of the memory layer ML in the Z-direction while keeping the wiring resistance of the conductive layer 120 to a relatively small value.

### Second Embodiment

### Structure

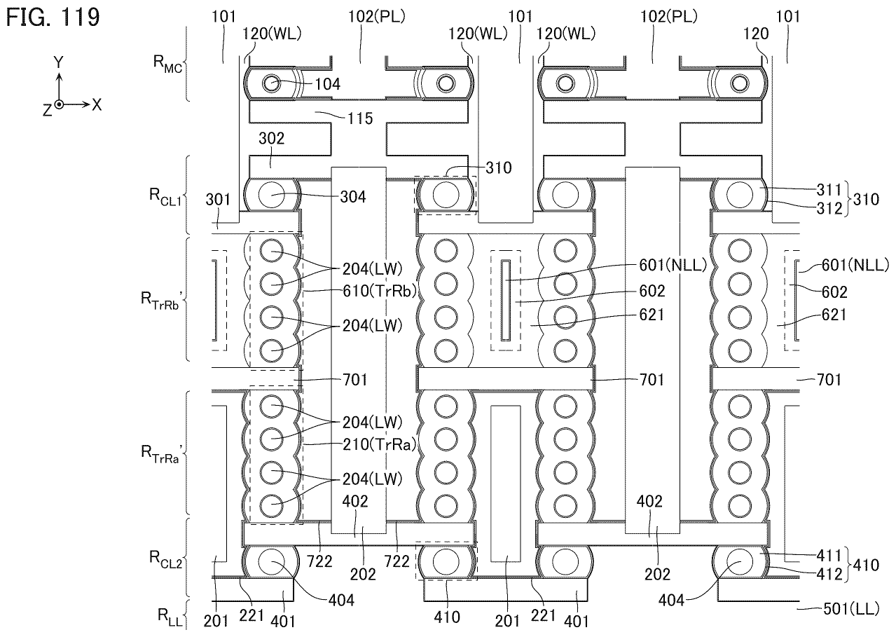

Next, with reference to FIG. 119, a semiconductor memory device according to a second embodiment is described. FIG. 119 is a schematic X-Y cross-sectional view illustrating a configuration of a part of the semiconductor memory device according to the second embodiment.

The semiconductor memory device according to the second embodiment is basically configured in the same way as the semiconductor memory device according to the first embodiment.

However, as described with reference to FIGS. 5 and 6, in the first embodiment, the transistor region R_{TrRa} corresponding to the transistor TrRa is provided on one side in the Y-direction with respect to the memory cell region R_{MC}, and the transistor region R_{TrRb} corresponding to the transistor TrRb is provided on the other side in the Y-direction with respect to the memory cell region R_{MC}.

On the other hand, as illustrated in FIG. 119, in the second embodiment, the transistor region R_{TrRa}′ corresponding to the transistor TrRa is provided on one side in the Y-direction with respect to the memory cell region R_{MC}, and the transistor region R_{TrRb}′ corresponding to the transistor TrRb is provided between the memory cell region R_{MC} and the transistor region R_{TrRa}′.

Between the transistor regions R_{TrRa}′, R_{TrRb}′, a plurality of insulating layers 701 arranged in the X-direction corresponding to the insulating layer 101 are provided. The insulating layer 701 extends in the X-direction and the Z-direction and divides the plurality of memory layers ML in the Y-direction. The insulating layer 701 includes, for example, silicon oxide (SiO₂).

The transistor regions R_{TrRa}′, R_{TrRb}′ are basically configured in the same way as the transistor regions R_{TrRa}, R_{TrRb}. However, in the transistor regions R_{TrRa}′, R_{TrRb}′, conductive layers 722 are provided instead of the conductive layers 222, 622. The conductive layers 722 are basically configured in the same way as the conductive layers 222, 622. However, the conductive layers 722 extend in the Y-direction from the transistor region R_{TrRa}′ connection wiring region Roz via the transistor region R_{TrRb}′, and have a function of electrically connecting the above-described one electrode of the transistor TrRa (FIG. 1), the above-described one electrode of the transistor TrRb (FIG. 1), and the word line WL (FIG. 1).

With this type of configuration, it is possible to further reduce the circuit area of the memory cell array MCA by reducing the number of connection wiring regions R_{CL1} for connecting the configurations between the respective regions.

### Other Embodiments

The semiconductor memory devices according to the first embodiment and the second embodiment are described. However, the semiconductor memory devices according to these embodiments are merely examples, and the specific configuration, and the like can be adjusted as appropriate.

For example, in the semiconductor memory devices according to the first embodiment and the second embodiment, the via-wiring 104 that functions as the bit line includes a conductive oxide, such as indium tin oxide (ITO). However, such a conductive oxide may be contained in the transistor structure 110 rather than in the via-wiring 104 that extends in the Z-direction. In addition, the via-wiring 104 and the transistor structure 110 may also contain another material or the like.

In the semiconductor memory devices according to the first embodiment and the second embodiment, the conductive layers 113, 215, 615, which function as the gate electrodes of the transistors TrC, TrRa, TrRb, may be opposed to only one of the upper surfaces and the lower surfaces of the semiconductor layers 111, 213, 613, which function as the channel regions of the transistors TrC, TrRa, TrRb.

In the semiconductor memory devices according to the first embodiment and the second embodiment, the semiconductor layers 111, 213, 613, which function as the channel regions of the transistors TrC, TrRa, TrRb may be opposed to the upper surfaces and the lower surfaces of the conductive layers 113, 215, 615, which function as the gate electrodes of the transistors TrC, TrRa, TrRb.

In the above-described description, the example in which the capacitor CpC is used as the memory portion connected to the transistor structure 110 is described. However, the memory portion does not have to be the capacitor CpC. For example, the memory portion may include a ferroelectric material, a ferromagnetic material, and a chalcogen material such as GeSbTe, or another material, and may store data using the characteristics of these materials. For example, in any of the structures described above, any of these materials may be contained in the insulating layer between the electrodes that form the capacitor CpC.

The manufacturing method of the semiconductor memory device according to the first embodiment and the second embodiment can also be adjusted as appropriate. For example, the order of any two of the above-described processes can be switched, or any two of the above-described processes can be executed simultaneously.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a first via-wiring extending in a first direction intersecting with a surface of the substrate;
a plurality of first semiconductor layers arranged in the first direction and electrically connected to the first via-wiring;
a plurality of memory portions arranged in the first direction and electrically connected to the plurality of first semiconductor layers;
a plurality of first gate electrodes arranged in the first direction and opposed to the plurality of first semiconductor layers;
a plurality of first wirings arranged in the first direction, extending in a second direction intersecting with the first direction, and electrically connected to the plurality of first gate electrodes;
a plurality of second semiconductor layers arranged in the first direction and electrically connected to the plurality of first wirings;
a plurality of second gate electrodes arranged in the first direction and opposed to the plurality of second semiconductor layers;
a second via-wiring extending in the first direction and electrically connected to the plurality of second gate electrodes; and
a second wiring extending in the first direction, electrically connected to the plurality of second semiconductor layers, and arranged with the plurality of second semiconductor layers in a third direction intersecting with the first direction and the second direction.

2. The semiconductor memory device according to claim 1, wherein
the plurality of second gate electrodes include two second gate electrodes adjacent in the first direction one another,
in the first direction, both end portions of one of the two second gate electrodes in the second direction are spaced from both end portions of the other of the two second gate electrodes in the second direction, and
in the first direction, both end portions of the one of the two second gate electrodes in the third direction are spaced from both end portions of the other of the two second gate electrodes in the third direction.

3. The semiconductor memory device according to claim 1, comprising
a plurality of insulating layers arranged in the first direction alternately with the plurality of first semiconductor layers, wherein
the plurality of second gate electrodes are provided at positions in the first direction corresponding to the respective plurality of insulating layers.

4. The semiconductor memory device according to claim 1, wherein
one of the plurality of second gate electrodes is provided between two second semiconductor layers adjacent to one another in the first direction among the plurality of second semiconductor layers, and opposed to each of the two second semiconductor layers.

5. The semiconductor memory device according to claim 1, wherein
the second semiconductor layer contains at least one element of gallium (Ga) or aluminum (Al), and contains indium (In), zinc (Zn), and oxygen (O).

6. The semiconductor memory device according to claim 1, wherein
the first gate electrode is opposed to a surface on one side and a surface on the other side of the first semiconductor layer in the first direction and a surface on one side and a surface on the other side of the first semiconductor layer in the second direction.

7. The semiconductor memory device according to claim 1, wherein
the memory portion includes:
a first electrode electrically connected to the first semiconductor layer,
a second electrode opposed to the first electrode; and
an insulating layer provided between the first electrode and the second electrode.

8. The semiconductor memory device according to claim 1, wherein
the first semiconductor layer contains at least one element of gallium (Ga) or aluminum (Al), and contains indium (In), zinc (Zn), and oxygen (O).

9. The semiconductor memory device according to claim 1, comprising:
a plurality of third semiconductor layers arranged in the first direction and electrically connected to the plurality of first wirings;
a plurality of third gate electrodes arranged in the first direction and opposed to the plurality of third semiconductor layers;
a third via-wiring extending in the first direction and electrically connected to the plurality of third gate electrodes; and
a plurality of third wirings arranged in the first direction, extending in the third direction, and electrically connected to the plurality of third semiconductor layers.

10. The semiconductor memory device according to claim 9, wherein
a position of the first via-wiring in the second direction is between a position of the second via-wiring in the second direction and a position of the third via-wiring in the second direction.

11. The semiconductor memory device according to claim 9, wherein
a position of the second via-wiring in the second direction is between a position of the first via-wiring in the second direction and a position of the third via-wiring in the second direction.

12. The semiconductor memory device according to claim 9, wherein
the plurality of third gate electrodes include two third gate electrodes adjacent in the first direction one another,
in the first direction, both end portions of one of the two third gate electrodes in the second direction are spaced from both end portions of the other of the two third gate electrodes in the second direction, and
in the first direction, both end portions of the one of the two third gate electrodes in the third direction are spaced from both end portions of the other of the two third gate electrodes in the third direction.

13. The semiconductor memory device according to claim 9, comprising
a plurality of insulating layers arranged in the first direction alternately with the plurality of first semiconductor layers, wherein
the plurality of third gate electrodes are provided on positions in the first direction corresponding to the respective plurality of insulating layers.

14. The semiconductor memory device according to claim 9, wherein
one of the plurality of third gate electrodes is provided between two third semiconductor layers adjacent to one another in the first direction among the plurality of third semiconductor layers, and opposed to each of the two third semiconductor layers.

15. The semiconductor memory device according to claim 9, wherein
the third semiconductor layer contains at least one element of gallium (Ga) or aluminum (Al), and contains indium (In), zinc (Zn), and oxygen (O).
